(19) United States
(12) Patent Application Publication
(10) Pub. No.: US 2005/0111106 A1
(43) Pub. Date: May 26, 2005

(54) Optical element assembly formed of multiple optical elements such as prisms, and image pickup apparatus using the same in image pickup function section

(76) Inventors: Kazuhiro Matsumoto, Hachioji-shi (JP); Yasuo Nakajo, Niiza-shi (JP); Hiroyuki Ando, Hachioji-shi (JP); Tetsuo Nagata, Hachioji-shi (JP); Yuji Imai, Hachioji-shi (JP)

Correspondence Address: STRAUB & POKOTYLO, 620 TINTON AVENUE, BLDG. B, 2ND FLOOR, TINTON FALLS, NJ, 07724, US

(21) Appl. No.: 10/978,303

(22) Filed: Oct. 29, 2004

(30) Foreign Application Priority Data
Oct. 31, 2003 (JP) 2003-373568
Oct. 31, 2003 (JP) 2003-373569
Oct. 31, 2003 (JP) 2003-373571

(51) Int. Cl. H05K 1/00; H01R 12/00; G02B 27/10

(52) U.S. Cl. 359/624

(57) ABSTRACT

An optical element assembly includes a first optical element, a second optical element, and a positioning holder member. The first optical element has engageably shaped portions in a peripheral portion of an effective area on a first injection surface through which the effective luminous flux passes. These engageably shaped portions respectively correspond to one engageably shaped portions formed on one opponent surface of the positioning holder member that opposes the first injection surface. The second optical element has engageably shaped portions in a peripheral portion of an effective area on a second incident surface through which the effective luminous flux passes. These engageably shaped portions respectively correspond to the other engageably shaped portions formed on the other opponent surface of the positioning holder member that opposes the second incident surface. The positioning holder member has in a predetermined portion, an optical diaphragm aperture that permits transmission of light between the one opponent surface and the other opponent surface. An image pickup apparatus includes the optical element assembly, an image pickup device, and an image data producing portion.

### CROSS-REFERENCE TO RELATED APPLICATIONS

This application is based upon and claims the benefit of priority from prior Japanese Patent Applications No. 2003-373568, filed Oct. 31, 2003; No. 2003-373569, filed Oct. 31, 2003, and No. 2003-373571, filed Oct. 31, 2003, the entire contents of all of which are incorporated herein by reference.

### BACKGROUND OF THE INVENTION

1. Field of the Invention

The present invention relates to an optical element assembly formed by assembling a plurality of optical element such as prisms. The invention further relates to an image pickup apparatus (any one of apparatuses such as a digital still camera, a mobile phone and personal computer having a camera functionality, and a video camera).

2. Description of the Related Art

In recent years, increasing miniaturization has advanced in the field of image pickup apparatuses, such as digital still cameras, cellular phones and personal computers having camera functionality, and video cameras. On the trend in the advancement of the miniaturization technology for image pickup apparatuses, there occur growing demands for miniaturization and/or thinning also for assemblies of image pickup functional sections built into the main bodies of such apparatuses.

Generally, optical systems of a coaxial system type are used for such assemblies as described above. The “coaxial system” refers to an optical system in which optical devices or elements, such as lenses, are arranged rotationally symmetric with respect to the optical axis of the optical system.

The number of lenses should be reduced to make the assembly compact. However, a small number of lenses make it difficult to reduce the aberration. To overcome this problem, optical apparatuses using an eccentric optical system have been proposed.

For example, prism optical systems using, for example, free-form surfaces are proposed in Patent References 1 to 5 described below.

Patent Reference 1 (Jpn. Pat. Appln. KOKAI Publication No. 2002-267928) discloses techniques for an optical-element assembly configuration as summarized here. The techniques are proposed to provide an image pickup lens that is small, light, excellent in telecentricity, and excellent in the properties of facilitating correction of astigmatism and the like and assembly processing. To achieve the provision, a configuration is formed using two, first and second lenses as configuration elements. The 1^{st} lens is the type of a negative meniscus, and the second lens is the type of a positive meniscus, and the two lenses (first and second lenses) are arranged in the order from an object such that a convex surface of the first lens surfaces the side of the object side and a convex surface of the 2^{nd} lens surfaces to the side of a diaphragm and an image plane. In addition, at least one surface of each of the two lenses is formed aspheric. The configuration is thus formed to satisfy specific conditions.

Patent Reference 2 (Jpn. Pat. Appln. KOKAI Publication No. 2002-320122) discloses technique as summarized here. According to the techniques, a configuration is formed such that an image pickup device, such as a CCD (charge coupled device), is mounted in a mobile phone to enable a user of the cellular phone to capture images with the mobile phone, which can easily be carried, and to transmit the images to communications destinations. Thereby, the user of the mobile phone need not have, for example, a digital camera, a personal computer, and the like. According to Patent Reference 2, an image pickup function section of the mobile phone is configured to include optical members having an image pickup device disposed on a substrate, a lens section for imaging an object image on a photoreceptive surface of the image pickup device, a leg portion for holding the lens section. The Patent Reference 2 describes that in comparison to a case where the leg portion is brought into abutment with the substrate, in a case where the leg portion is brought into abutment at an abutting force of at least 5 g and at most 500 g with a surface of the image pickup device, the lens section and the photoreceptive surface of the image pickup device can be positioned along the optical axial at higher precision. In addition, the Patent Reference 2 describes that setting the abutting force to 5 g or greater enables preventing image blurring that can occur in association with backlash movement of the optical member due to handshaking at the time of image pickup; and setting the abutting force to 500 g or less enables restraining the image pickup device from damage, functional failure, and the like.

Patent Reference 3 (Jpn. Pat. Appln. KOKAI Publication No. 11-326766) discloses an optical element assembly used to provide a small, thin, and low-cost imaging optical system and an apparatus using that system. The assembly is configured such that the imaging optical system for forming images of objects includes a diaphragm, an object-side reflecting surface arranged closer to an object side than the diaphragm an image-side surface arranged closer to an image side than the diaphragm. The object-side and image-side reflecting surface are each formed aspherical to impart luminous power to luminous fluxes at the time of reflection, and a low-pass filter for cutting a high frequency component is provided between the object-side and image-side reflecting surfaces.

In the field of imaging optical systems for use with apparatuses and instruments, such as video cameras, digital still cameras, film scanners, and endoscopes, also optical systems themselves are required to be compact and lightweight on the trend toward increasing miniaturization of image pickup devices. In recent years, products such as mobile phones, PDAs (personal digital assistants), notebook personal computers (notebook computers) including an electronic image pickup system element has appeared on the market, so that such the optical system is strongly required to be further thinned.

In response to the requirements under the circumstances as described above, techniques relative to configurations of image pickup function sections have been proposed as disclosed in publications such as Patent Reference 4 (Jpn. Pat. Appln. KOKAI Publication No. 2002-196243) and Patent Reference 5 (Jpn. Pat. Appln. KOKAI Publication No. 2003-084200). The proposed configurations are each formed by combining prisms to implement a high-performance, low-cost

As such are the circumstances, among the above-described problems to be encountered when particularizing the techniques into products or merchandizes in the subject technical field, there is a great demand for implementing an optical element assembly and an image pickup apparatus having the optical element assembly configured to enable the retention and connection of the optical elements such as multiple prisms so that inter-position relationship therebetween is maintained in a predetermined relationship.

Further, among the above-described problems to be encountered when to particularizing the techniques into products or merchandizes in the subject technical field, there is a great demand for implementing an optical element assembly and an image pickup apparatus having the optical element assembly configured to enabling avoiding detrimental things such as unnecessary luminous flux occurrence and influence thereof.

In addition, among the above-described problems to be encountered when to particularizing the techniques into products or merchandizes in the subject technical field, there is a great demand for implementing an optical element assembly and an image pickup apparatus having the optical element assembly that enable retention and connection in an apparatus and imaging optical system and to further provide a high-performance imaging optical system formed such that the optical path is folded on only three surfaces and the image pickup device is exceptionally thinned in the size vertical direction, whereby to impart desired characteristics thereto to serve as an optical element assembly.

Thus, the publications disclose the techniques that use multiple prisms in combination, of which appropriate optical characteristics are selected for the optical elements, the techniques thus proposed are not extended beyond those as summarized above. More specifically, the publications do not necessarily propose regarding solutions of potential problems to be encountered in particularizing the techniques into the form of products or merchandizes. The problems are, for example:

how to implement retention and connection of the optical elements so that inter-position relationship therebetween is maintained in a predetermined relationship;

what type of a configuration should be to avoid detrimental things such as unnecessary luminous flux occurrence and influence thereof;

how to secure enhanced manufacturability; and

what type of a configuration should be to enhance immunity against the influence of dust. optical elements and assembly of these types to be appropriate and maintained with high precision.

### BRIEF SUMMARY OF THE INVENTION

According to a first aspect of the present invention, there is provided an optical element assembly comprising:

a first optical element which includes a prism configured such that incident light arrived from an object and input to a first predetermined incident surface is reflected by a predetermined reflecting surface having power and injected from a first predetermined injection surface;

a second optical element which includes a prism configured such that incident light arrived from the first optical element and input to a second predetermined incident surface is reflected by a predetermined reflecting surface having power and injected from a second predetermined injection surface; and

a positioning holder member to hold the first optical element and the second optical element so that relative positions of the first optical element and the second optical element are maintained in a predetermined relationship,

wherein the first optical element has engageably shaped portions formed in a peripheral portion of an effective area on the first injection surface through which an effective luminous flux passes, the engageably shaped portions respectively corresponding to one engageably shaped portions formed on one opponent surface of the positioning holder member that opposes the first injection surface,

wherein the second optical element has engageably shaped portions formed in a peripheral portion of an effective area on the second incident surface through which an effective luminous flux passes, the engageably shaped portions respectively corresponding to the other engageably shaped portions formed on the other opponent surface of the positioning holder member that opposes the second incident surface, and

wherein the positioning holder member has, formed in a predetermined portion, an optical diaphragm aperture that permits transmission of light between the one opponent surface and the other opponent surface.

According to a second aspect of the present invention, there is provided an image pickup apparatus comprising:

(A) an optical element assembly comprising:

(a1) a first optical element which includes a prism configured such that incident light arrived from an object and input to a first predetermined incident surface is reflected by a predetermined reflecting surface having power and injected from a first predetermined injection surface;

(a2) a second optical element which includes a prism configured such that incident light arrived from the first optical element and input to a second predetermined incident surface is reflected by a predetermined reflecting surface having power and injected from a second predetermined injection surface; and

(a3) a positioning holder member to hold the first optical element and the second optical element so that relative positions of the first optical element and the second optical element are maintained in a predetermined relationship,

wherein the first optical element has engageably shaped portions formed in a peripheral portion of an effective area on the first injection surface through which an effective luminous flux passes, the engageably shaped portions respectively corresponding to one engageably shaped portions formed on one opponent surface of the positioning holder member that opposes the first injection surface,

wherein the second optical element has engageably shaped portions formed in a peripheral portion of an effective area on the second incident surface through which an effective luminous flux passes, the engageably shaped portions respectively corresponding to the other engageably shaped portions formed on the other opponent surface of the positioning holder member that opposes the second incident surface, and

wherein the positioning holder member has, formed in a predetermined portion, an optical diaphragm aperture that permits transmission of light between the one opponent surface and the other opponent surface, and

(B) an image pickup device adapted to perform photoelectrical conversion of an optical image of a luminous flux injected from the predetermined injection surface of the optical element assembly; and

(C) an image data producing circuit to produce image data adaptable to at least one of predetermined recording and communication in accordance with an output signal of the image pickup device.

In the first and second aspects, there is provided an optical element assembly in which the first optical element including the prism and the second optical element including the prism are disposed oppositely with the positioning holder member having the flux transmission aperture interposed therebetween, and which is entirely integrated via the engageably shaped portions in the peripheral portion of the effective area on the first injection surface through which the effective luminous flux passes. Therefore, according to the first and second aspects of the invention, there can be provided an optical element assembly capable of holding or connecting a plurality of optical elements so that relative positions of the optical elements are maintained in a predetermined relationship, and an image pickup apparatus comprising the optical element assembly.

According to a third aspect of the present invention, there is provided an optical element assembly comprising:

a first optical element which includes a prism configured such that incident light arrived from an object and input to a first predetermined incident surface is reflected by a predetermined reflecting surface having power and injected from a first predetermined injection surface;

a second optical element which includes a prism configured such that incident light arrived from the first optical element and input to a second predetermined incident surface is reflected by a predetermined reflecting surface having power and injected from a second predetermined injection surface; and

a positioning holder member to hold the first optical element and the second optical element so that relative positions of the first optical element and the second optical element are maintained in a predetermined relationship,

wherein the first optical element has engageable protrusion portions formed in a peripheral portion of an effective area on the first injection surface through which an effective luminous flux passes, the engageable protrusion portions being provided to engage one opponent surface of a positioning holder member that opposes the first injection surface,

wherein the second optical element has engageable protrusion portions formed in a peripheral portion of an effective area on the second incident surface through which an effective luminous flux passes, the engageable protrusion portions being provided to engage the other opponent surface of the positioning holder member that opposes the second incident surface,

wherein the positioning holder member has, formed in a predetermined portion, an optical diaphragm aperture that permits transmission of light between the one opponent surface and the other opponent surface, and additionally comprises, respectively on the one opponent surface and the other opponent surface, engageable recess portions that are formed to respectively correspond to and to be engageable with the engageable protrusion portions of the first optical element and the engageable protrusion portions of the second optical element.

According to a fourth aspect of the present invention, there is provided an image pickup apparatus comprising:

(A) an optical element assembly comprising:

(a1) a first optical element which includes a prism configured such that incident light arrived from an object and input to a first predetermined incident surface is reflected by a predetermined reflecting surface having power and injected from a first predetermined injection surface;

(a2) a second optical element which includes a prism configured such that incident light arrived from the first optical element and input to a second predetermined incident surface is reflected by a predetermined reflecting surface having power and injected from a second predetermined injection surface; and

(a3) a positioning holder member to hold the first optical element and the second optical element so that relative positions of the first optical element and the second optical element are maintained in a predetermined relationship,

wherein the first optical element has engageable protrusion portions formed in a peripheral portion of an effective area on the first injection surface through which an effective luminous flux passes, the engageable protrusion portions being provided to engage one opponent surface of the positioning holder member that opposes the first injection surface,

wherein the second optical element has engageable protrusion portions formed in a peripheral portion of an effective area on the second incident surface through which an effective luminous flux passes, the engageable protrusion portions being provided to engage the other opponent surface of the positioning holder member that opposes the incident surface,

wherein the positioning holder member has, formed in a predetermined portion, an optical diaphragm aperture that permits transmission of light between the one opponent surface and the other opponent surface, and additionally has, respectively on the one opponent surface and the other opponent surface, engageable recess portions that are formed to respectively correspond to and to be engageable with the engageable protrusion portions of the first optical element and the engageable protrusion portions of the second optical element, and

(B) an image pickup device adapted to perform photoelectrical conversion of an optical image of a luminous flux injected from the predetermined injection surface of the optical element assembly; and

(C) an image data producing circuit to produce image data adaptable to at least one of predetermined recording and communication in accordance with an output signal of the image pickup device.

In the third and fourth aspects, there is provided an optical element assembly configured to provide an optical-shield circuit at a portion excluding the optical diaphragm aperture of the positioning holder member, and so that light cannot transmit between the first optical element including the prism and the second optical element including the prism. Therefore, according to the third and fourth aspects of the invention, there can be provided an optical. element assembly capable of suppressing occurrence of unnecessary luminous flux and avoiding its influence, and an image pickup apparatus comprising the optical element assembly.

According to a fifth aspect of the present invention, there is provided an optical element assembly comprising:

a first optical element which includes a prism configured such that incident light arrived from an object and input to a first predetermined incident surface is reflected by a predetermined reflecting surface having power and injected from a first predetermined injection surface;

a second optical element which includes a prism configured such that incident light arrived from the first optical element and input to a second predetermined incident surface is reflected by a predetermined reflecting surface having power and injected from a second predetermined injection surface; and

a diaphragm member which connects the first optical element and the second optical element so that relative positions of the first optical element and the second optical element are maintained in a predetermined relationship, and which is interposed in a predetermined position between the first optical element and the second optical element,

wherein the first optical element has engageably shaped portions formed in a peripheral portion of an effective area on the first injection surface through which an effective luminous flux passes, the engageably shaped portions respectively corresponding to engageably shaped portions formed in a peripheral portion of an effective area on the second incident surface of the second optical element through which an effective luminous flux passes,

wherein the second optical element has the engageably shaped portions formed in the peripheral portion of an effective area on the second incident surface through which the effective luminous flux passes, the engageably shaped portions respectively corresponding to the engageably shaped portions provided in the peripheral portion of the effective area, through which the effective luminous flux passes, on the first injection surface of the first optical element, and

wherein the diaphragm member has, formed in a predetermined portion, an optical diaphragm aperture that permits transmission of the luminous flux from the first injection surface of the first optical element to the second incident surface of the second optical element.

According to a sixth aspect of the present invention, there is provided an image pickup apparatus comprising:

(A) an optical element assembly comprising:

(a1) a first optical element which includes a prism configured such that incident light arrived from an object and input to a first predetermined incident surface is reflected by a predetermined reflecting surface having power and injected from a second predetermined injection surface;

(a2) a second optical element which includes a prism configured such that incident light arrived from the first optical element and input to a second predetermined incident surface is reflected by a predetermined reflecting surface having power and injected from a second predetermined injection surface, the first optical element and the second optical element being connected to each other so that relative positions of the first optical element and the second optical element are maintained in the predetermined relationship; and

(a3) a diaphragm member interposed in a predetermined position between the first optical element and the second optical element,

wherein the first optical element has engageably shaped portions formed in a peripheral portion of an effective area on the first injection surface through which an effective luminous flux passes, the engageably shaped portions respectively corresponding to engageably shaped portions formed in a peripheral portion of an effective area on the second incident surface of the second optical element through which an effective luminous flux passes,

wherein the second optical element has the engageably shaped portions formed in the peripheral portion of an effective area on the second incident surface through which the effective luminous flux passes, the engageably shaped portions respectively corresponding to the engageably shaped portions provided in the peripheral portion of the effective area, through which the effective luminous flux passes, on the first injection surface of the first optical element, and

wherein the diaphragm member has, formed in a predetermined portion, an optical diaphragm aperture that permits transmission of the luminous flux from the first injection surface of the first optical element to the second incident surface of the second optical element, and

(B) an image pickup device adapted to perform photoelectrical conversion of an optical image of a luminous flux injected from the predetermined injection surface of the optical element assembly; and

(C) an image data producing circuit to produce image data adaptable to at least one of predetermined recording and communication in accordance with an output signal of the image pickup device.

In the fifth and sixth aspects, there is provided an optical element assembly configured such that the engageably shaped portions provided in the first optical element including the prism and the second optical element including the prism are directly engaged, whereby relative positions thereof are maintained in the predetermined relationship. Therefore, according to the fifth and sixth aspects of the invention, there can be provided an optical element assembly capable of providing proper relative positions of a plurality of optical elements in this kind of apparatus or assembly, and maintaining the relative positions at high precision, and an image pickup apparatus comprising the optical element assembly.

Advantages of the invention will be set forth in the description which follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic configuration view showing an outline of an image pickup apparatus to which an optical element assembly according to a first embodiment of the present invention is applied;

FIG. 2 shows the configuration of an optical system of the optical element assembly according to the first embodiment of the invention;

FIG. 3 is a perspective view showing a state where a positioning holder member integrally holds a first optical element and a second optical element of the optical element assembly according to the first embodiment of the invention;

FIG. 4 is a side view showing the state shown in FIG. 3;

FIG. 5 is an exploded perspective view showing a state where the first optical element, the second optical element, and the positioning holder member according to the first embodiment of the invention are disconnected from one another;

FIGS. 6A and 6B are, respectively, a perspective view showing the structure of a first injection surface as a luminous flux injection surface of the first optical element according to the first embodiment of the invention, and a perspective view showing the structure of a second incident surface as a luminous flux incident surface of the second optical element according to the first embodiment;

FIGS. 7A and 7B are, respectively, plan views showing the shapes of obverse and reverse surfaces of the positioning holder member according to the first embodiment of the invention;

FIGS. 8A and 8B are, respectively, a perspective view showing the structure of a first injection surfaces as a luminous flux injection surface of the first optical element according to a second embodiment of the invention and a perspective view showing the structure of a second incident surface as a luminous flux incident surface of the second optical element according to the second embodiment;

FIGS. 9A and 9B are, respectively, plan views showing the shapes of obverse and reverse surfaces of a positioning holder member according to the second embodiment of the invention;

FIGS. 10A and 10B respectively show the structures of a first injection surface as a luminous flux injection surface of a first optical element and an opponent surface of a positioning holder member according to a third embodiment of the invention, FIG. 10A being an exploded perspective view showing the state where the first optical element and the positioning holder member are disconnected from each other, and FIG. 10B being an enlarged cross-sectional view of an important portion thereof;

FIGS. 11A and 11B are schematic configuration views individually showing examples of application to digital cameras according to a fourth embodiment of the invention, FIG. 11A showing an example of application of an optical element assembly to an image pickup system of a digital camera, and FIG. 11B showing an example of application of an optical element assembly to a viewfinder system of a digital camera;

FIGS. 12A and 12B are schematic configuration views individually showing examples applications to a personal computer according to a fifth embodiment of the invention, FIG. 12A being a side view of a notebook personal computer, and FIG. 12B being a schematic cross-sectional view showing an important portion thereof;

FIGS. 13A to 13C are schematic configuration views individually showing example applications of a device according to a sixth embodiment of the invention to a mobile phone, FIG. 13A being a plan view, FIG. 13B being a side view, and a FIG. 13C being a schematic cross-sectional view showing an schematic configuration of an important portion thereof;

FIG. 14 is a side view cutaway of the configuration having a connection relationship between the luminous flux injection surface of the first optical element, the second optical element, and both sides of a positioning holder member in an optical element assembly according to a seventh embodiment of the invention;

FIGS. 15A and 15B are, respectively, perspective views showing the structures of the first injection surface as the luminous flux injection surface of the first optical element and the second incident surface as the luminous flux incident surface of the second optical element in the optical element assembly according to the seventh embodiment of the invention;

FIGS. 16A to 16C show the structure of the positioning holder member of the optical element assembly according to the seventh embodiment of the invention, FIG. 16A being a plan view showing the shape of a surface of the positioning holder member, FIG. 16B being a cross-sectional view taken along a line 16B-16B, and FIG. 16C being a plan view showing the reverse side of the positioning holder member;

FIGS. 17A to 17C are views respectively corresponding to FIGS. 15A to 15C and show a modified example of the positioning holder member of the optical element assembly according to the seventh embodiment of the invention, FIG. 17A being a plan view showing the shape of the surface of the positioning holder member, FIG. 17B being a cross-sectional view taken along a line 17B-17B, and FIG. 17C being a plan view showing the reverse side of the positioning holder member;

FIGS. 18A to 18C show the configuration of an optical element assembly according to an eighth embodiment of the invention, FIG. 18A being a cross-sectional view of a major portion, and FIGS. 18B and 18C being cross-sectional views individually showing modified examples of the positioning holder member;

FIG. 19 is an exploded perspective view showing the state where a first optical element, a second optical element, and a diaphragm member of the optical element assembly according to a twelfth embodiment of the invention are disconnected from one another;

FIGS. 20A and 20B show the optical element assembly according to the twelfth embodiment of the invention, FIG. 20A being a cross-sectional view showing the state where the first optical element and second optical element thereof are integrally held through the diaphragm member, FIG. 20B being a cross-sectional view showing a partially modified example of the assembly of FIG. 20A; and

FIGS. 21A to 21C show the structure of the diaphragm member of the optical element assembly according to the twelfth embodiment of the invention, FIG. 21A being a plan view showing the shape of the obverse side of the diaphragm member, FIG. 21B being a cross-sectional view taken along a line 21B-21B of FIG. 21A, and FIG. 21C being a plan view showing the shaping of the reverse side of the diaphragm member.

### DETAILED DESCRIPTION OF THE INVENTION

Reference will now be made in detail to the embodiments of the invention as illustrated in the accompanying drawings, in which like reference numerals designate like or corresponding parts.

(First Emobodiment)

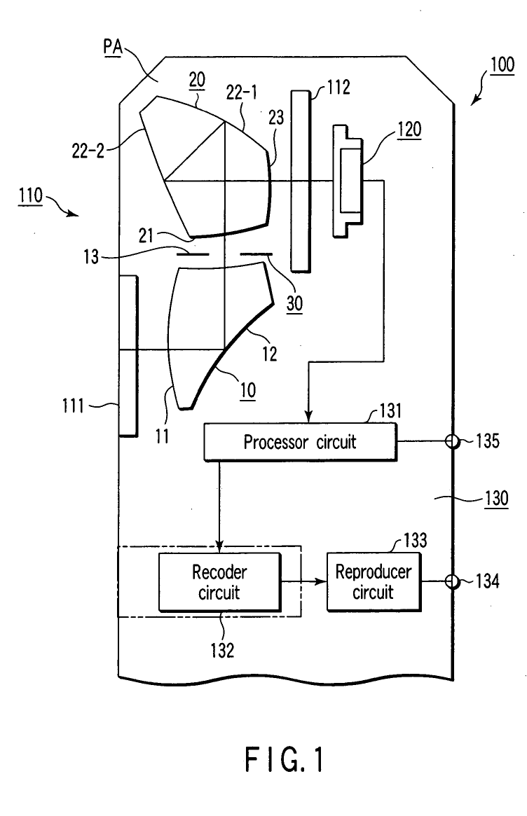

FIG. 1 is a schematic configuration view showing an outline of an image pickup apparatus 100 to which an optical element assembly PA according to a first embodiment of the present invention is applied. The image pickup apparatus 100 has an image pickup optical system 110, an image pickup device 120, and an image data producing circuit 130.

The image pickup optical system 110 is configured of an optical element assembly PA as a main component held by a positioning holder member 30 that has a luminous flux transmission opening in a manner that two elements, namely a first optical element 10 including a prism and a second optical element 20 including a prism, are maintained in predetermined relative positions. Cover glasses are shown with reference numerals 111 and 112, and one or both of which may be an IR cut filters having infrared light shielding functionality. The positioning holder member 30 has a functional section working as a diaphragm. The detail of the optical element assembly PA will be described below.

The image pickup device 120 performs photoelectrical conversion of an optical image of a luminous flux injected from the optical element assembly PA.

The image data producing circuit 130 processes a signal photoelectrically converted by the image pickup device 120. The image data producing circuit 130 is provided with a processor circuit 131, a recorder circuit 132, and a reproducer circuit 133. The processor circuit 131 can be used by necessity to perform compression or expansion of data, such as image data, in correspondence to a signal photoelectrically converted by the image pickup device 120. The recorder circuit 132 records the image data processed by the processor circuit 131 into a recording medium (for which memory card is usable). The reproducer circuit 133 is capable of performing reproduction, appropriately upon request, of image data recorded in the recorder circuit 132 and outputting the data from an output terminal 134. Meanwhile, the recorder circuit 132 is capable of communicating with, for example, an external device via a terminal 135.

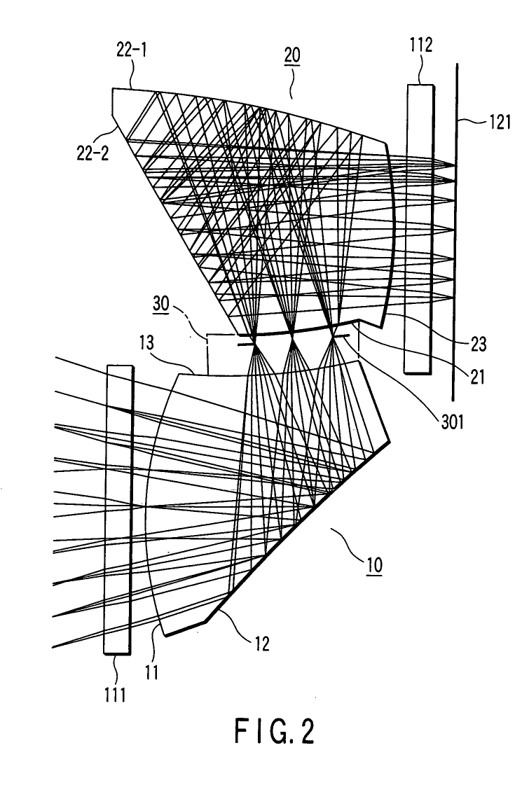

FIG. 2 shows the configuration of an optical system of the optical element assembly PA. As shown in FIG. 2, the first optical element 10 of the optical element assembly PA is formed of a prism arranged such that incident light arrived from an object and input to a first predetermined incident surface 11 is reflected by a predetermined reflecting surface 12 having power, and the light is injected from a first predetermined injection surface 13. The second optical element 20 of the optical element assembly PA is formed of a prism arranged such that incident light arrived from the first optical element 10 and input to a second predetermined incident surface 21 is reflected by a predetermined reflecting surfaces 22-1 and 22-2 having power, and the light is injected from a second predetermined injection surface 23.

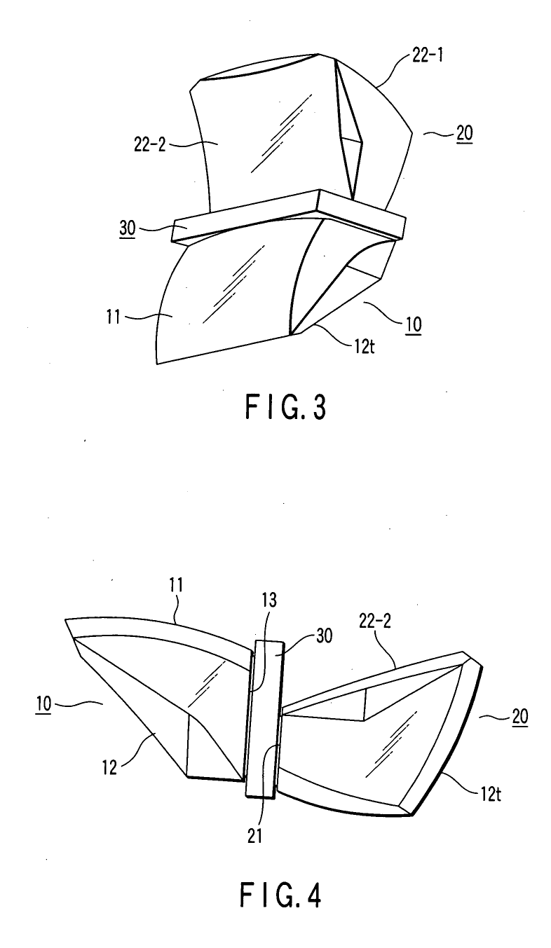

In FIG. 2, reference numeral 121 denotes a photoreceptive surface of the image pickup device 120. Referring back to FIG. 1, the positioning holder member 30 is interposed between the first optical element 10 and the second optical element 20, and a functional section 301 (shown in FIG. 3) is provided to the positioning holder member 30.

The optical system of the optical element assembly PA has reflecting surfaces of free-form surfaces or the like more than at least two surfaces. The free-form surface means a curved surface which is rotationally asymmetrical with respect to the optical axis of the light beam which strikes the surface or the optical axis of the light beam which exits from the surface and has only one mirror image surface along these optical axes.

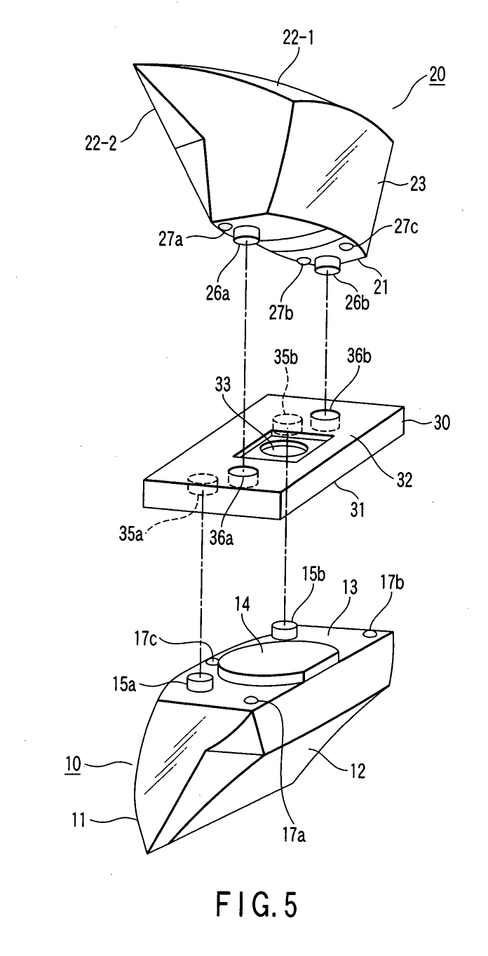

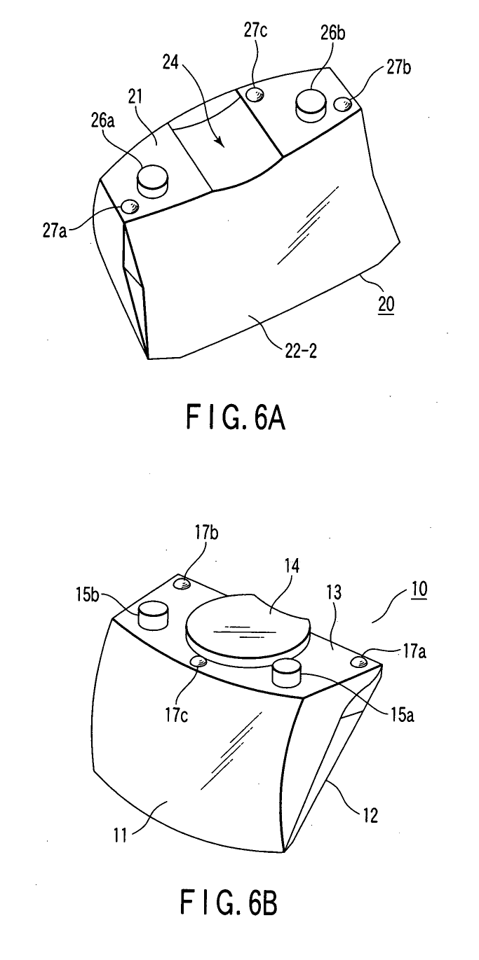

FIG. 3 is a perspective view showing a state where the positioning holder member 30 integrally holds the first optical element 10 and the second optical element 20 of the optical element assembly PA. FIG. 4 is a side view of the same state as FIG. 3, in which the positioning holder member 30 integrally holds the first optical element 10 and the second optical element 20. FIG. 5 is an exploded perspective view showing a state where the first optical element 10, the second optical element 20, and the positioning holder member 30 are disconnected from one another. FIGS. 6A and 6B are, respectively, a perspective view showing the structure of a luminous flux injection surface of the first optical element 10 and a perspective view showing the structure of a luminous flux incident surface of the second optical element 20.

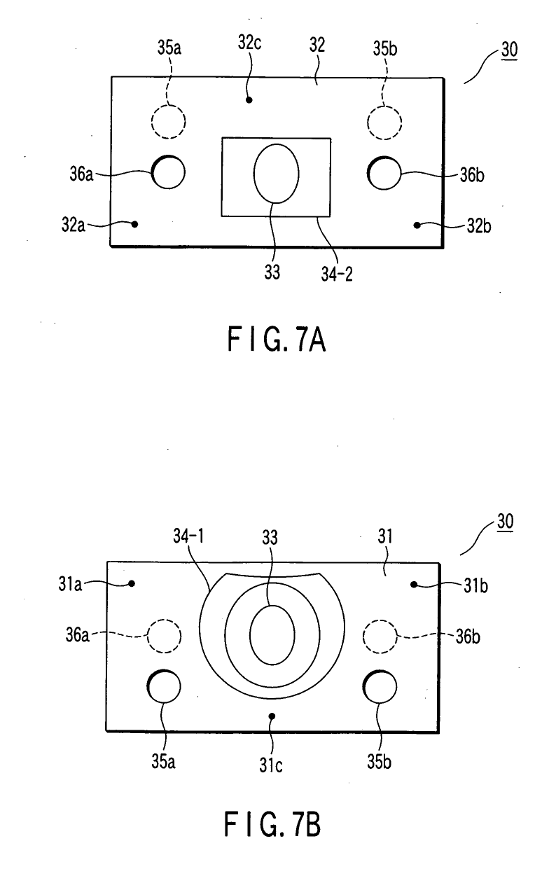

FIGS. 7A and 7B are, respectively, plan views showing the shapes of obverse and reverse surfaces of the positioning holder member 30.

As shown in FIGS. 3, 7A, and 7B, the first optical element 10 has engageably shaped portions 15a and 15b individually formed of short circularly-columnar protrusion portions in a peripheral portion of an effective area 14 on the first injection surface 13 through which an effective luminous flux passes. The engageably shaped portions 15a and 15b respectively correspond to one engageably shaped portions 35a and 35b formed on a one opponent surface 31 of the positioning holder member 30 in opposition to the first injection surface 13 of the first optical element 10. The second optical element 20 has engageably shaped portions 26a and 26b individually formed of similar short circularly-columnar protrusion portions in a peripheral portion of an effective area 24 on the second incident surface 21 through which an effective luminous flux passes. The engageably shaped portions 26a and 26b respectively correspond to other engageably shaped portions 36a and 36b formed on an other opponent surface 32 of the positioning holder member 30 in opposition to the second incident surface 21 of the second optical element 20.

The positioning holder member 30 has in a substantially central portion thereof an optical diaphragm aperture 33 that permits transmission of the luminous flux between the one opponent surface 31 and the other opponent surface 32. The aperture 33 is a practical example of the functional section 301 as being the optical diaphragm already described in conjunction with FIG. 2. In addition, the positioning holder member 30 has on the one opponent surface 31 the one engageably shaped portions 35a and 35b individually formed of recess portions (bottomed circular openings in the present embodiment), and has on the other opponent surface 32 the other engageably shaped portions 36a and 36b individually formed of recess portions (bottomed circular openings in the present embodiment).

The engageably shaped portions 15a and 15b are engaged with the one engageably shaped portions 35a and 35b. Concurrently, the engageably shaped portions 26a and 26b are engaged with the other engageably shaped portions 36a and 36b. Thereby, the first optical element 10 and the second optical element 20 are integrally connected through the positioning holder member 30 being interposed therebetween to maintain a predetermined positional relationship.

The optical system of the optical element assembly PA has at least two reflection surfaces having free-form surface shapes. The free-form surface is rotationally asymmetric with respect to the optical axis of a luminous flux to be input to the surface or the optical axis of a luminous flux to be injected from the surface, and refers to a curved surface having a single symmetric surface along to the axis.

Reference is now made to FIGS. 6A and 6B. As shown therein, first posture adjustment portions 17a to 17c are formed in predetermined portions on the first injection surface 13 that are segregated at predetermined distances from the engageably shaped portions 15a and 15b and that are out of the effective area 14. The first posture adjustment portions 17a to 17c are each formed of a semispherical protrusion portion to adjust the relative posture of the first optical element 10 to the positioning holder member 30. Specifically, these adjustment portions 17a to 17c are pre-adjusted in height to adjust an opposite-surface tilt angle of the first injection surface 13 of the first optical element 10 to the one opponent surface 31 of the positioning holder member 30, whereby to perform the posture adjustment.

In addition, second posture adjustment portions 27a to 27c are formed in predetermined portions on the second incident surface 21 that are segregated at predetermined distances from the engageably shaped portions 26a and 26b and that are out of the effective area 24. The second posture adjustment portions 27a to 27c are each formed of a semispherical protrusion portion to adjust the relative posture of the second optical element 20 to the positioning holder member 30. Specifically, these adjustment portions 27a to 27c are pre-adjusted in height to adjust opposite-surface tilt angles of the second incident surface 21 of the second optical element 20 and the other opponent surface 32 of the positioning holder member 30, whereby to perform the posture adjustment.

With reference to FIGS. 7A and 7A, first abutment portions 31a to 31c to abut the respective first posture adjustment portions 17a to 17c formed in the first optical element 10 are set in predetermined portions of the one opponent surface 31 of the positioning holder member 30.

In addition, second abutment portions 32a to 32c to abut the respective second posture adjustment portions 27a to 27c formed on the side of the second optical element 20 are set in predetermined portions of the other opponent surface 32 of the positioning holder member 30.

(Second Embodiment)

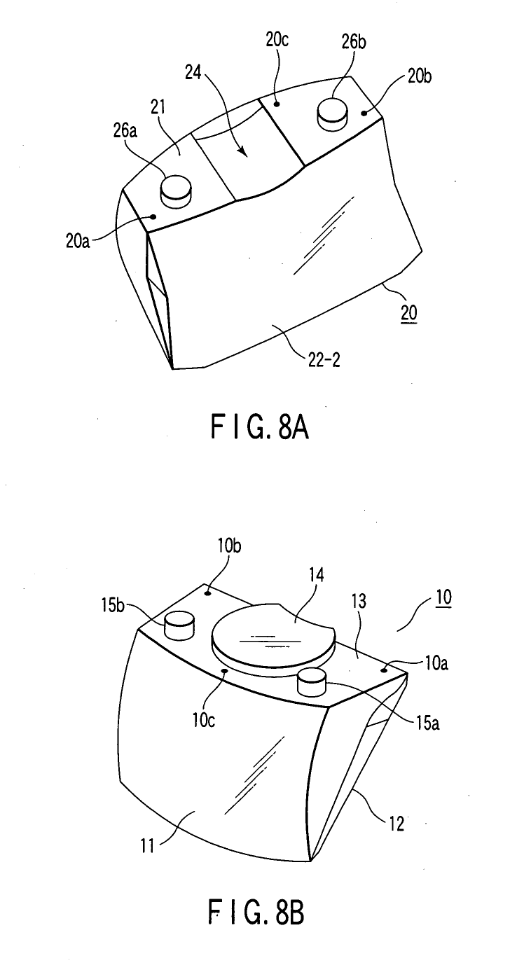

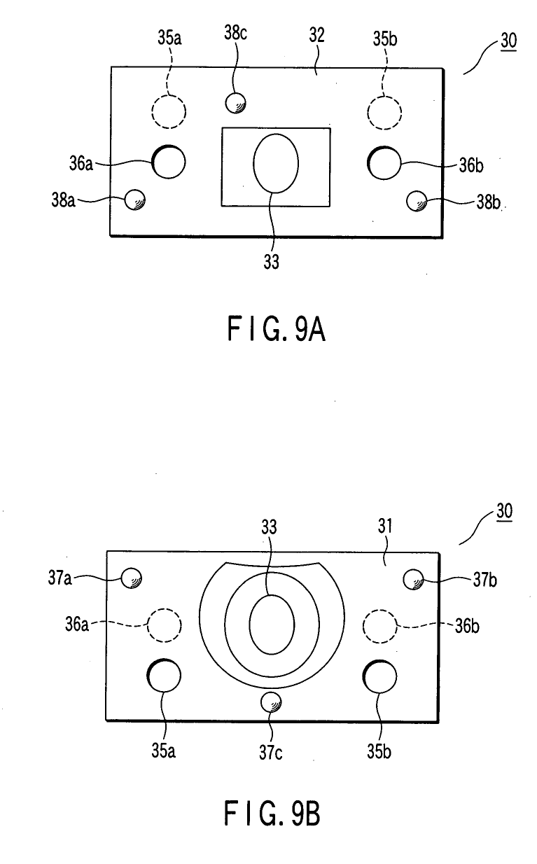

FIGS. 8A and 8B are, respectively, a perspective view showing the structure of a first injection surfaces 13 as a luminous flux injection surface of a first optical element 10 according to a second embodiment of the present invention, and a perspective view showing the structure of a second incident surfaces 21 as a luminous flux incident surface of a second optical element 20 according to the second embodiment. FIGS. 9A and 9B are, respectively, plan views showing the shapes of obverse and reverse surfaces of a positioning holder member 30 according to the second embodiment. Primarily the second embodiment is different from the first embodiment in that first and second posture adjustment portions are provided on the side of the positioning holder member 30.

With reference to FIGS. 9A and 9B, first positioning-holder-member-side posture adjustment portions 37a to 37c, each of which is formed of a semispherical protrusion portion, are formed on the one opponent surface 31 of the positioning holder member 30. In addition, second positioning-holder-member-side posture adjustment portions 38a to 38c, each of which is formed of a semispherical protrusion portion, are formed on the other opponent surface 32 of the positioning holder member 30.

With reference to FIGS. 8A and 8B, first-optical-element-side abutment portions 10a to 10c to abut the respective first positioning-holder-member-side posture adjustment portions 37a to 37c are set on the first injection surface 13 of the first optical element 10. In addition, second-optical-element-side abutment portions 20a to 20c to abut the respective second positioning-holder-member-side posture adjustment portions 38a to 38c are set on the second incident surface 21 of the second optical element 20.

(Third Embodiment)

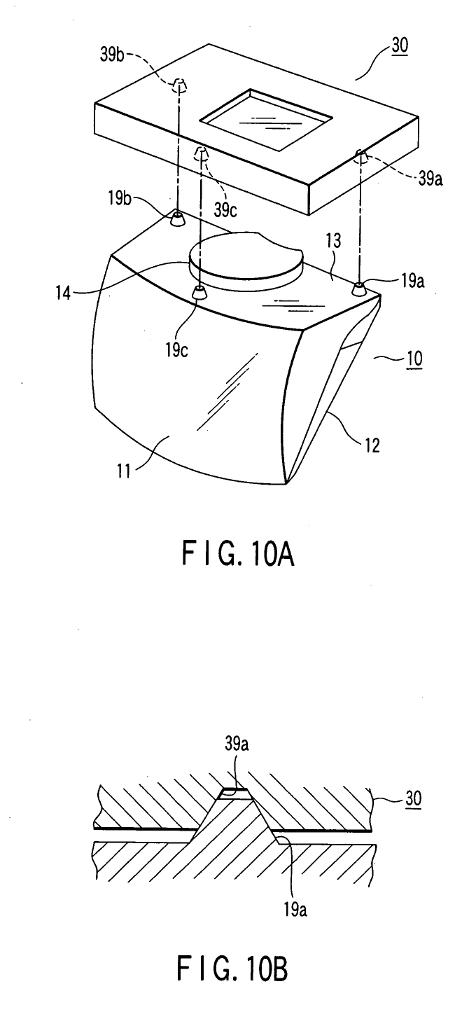

FIGS. 10A and 10B respectively show the structures of a luminous flux injection surface of a first optical element 10 and one opponent surface 31 of a positioning holder member 30 according to a third embodiment of the invention. More specifically, FIG. 10A is an exploded perspective view showing the state where the first optical element 10 and the positioning holder member 30 are disconnected from each other, and FIG. 10B is an enlarged cross-sectional view of an important portion thereof. Primarily, the third embodiment is different from the first embodiment as follows. Engageably shaped portions of a first optical element 10 and/or a second optical element 20 are individually formed as being pyramidal protrusion portions so as to be shared for both positioning and engagement functional section and posture-adjustment functional section. Consequently, according to the third embodiment, a significant advantage can be exhibited in that the configuration is simplified.

Referring to FIGS. 10A and 10B, pyramidal protrusion portions 19a to 19c each formed to be a pyramidal body or to include a portion of a pyramidal body are formed on a first injection surface 13 of the first optical element 10. Pyramidal recess portions 39a to 39c are formed on the one opponent surface 31 of the positioning holder member 30, in which the recess portions 39a to 39c respectively have shapes engageable with the pyramidal protrusion portions 19a to 19c and having surface portions along outer circumferential surfaces of the pyramidal protrusion portions 19a to 19c. In the present embodiment, the positioning and engageably shaped portions are shared for use as the posture adjustment portions whereby to simplify the structure.

(Fourth Embodiment)

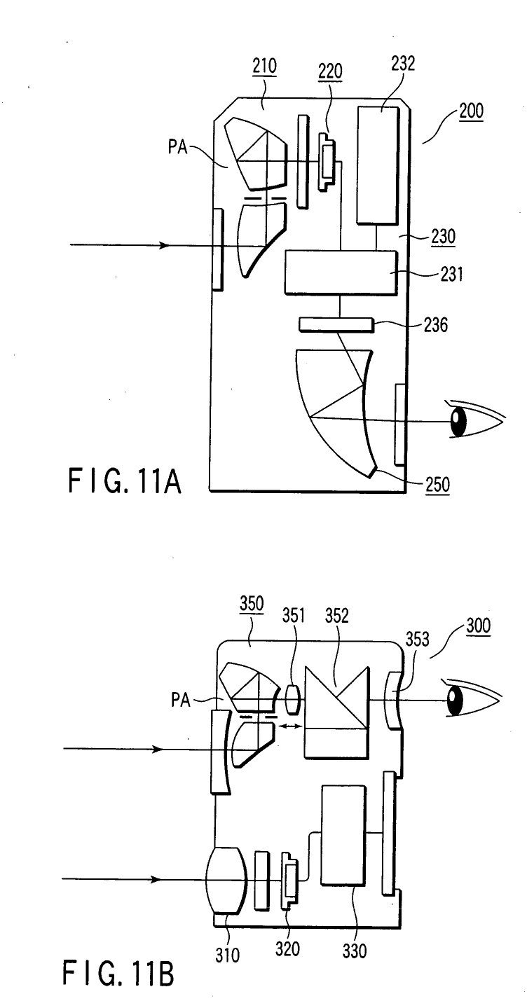

FIGS. 11A and 11B individually show schematic configurations of digital cameras (examples of application of an optical element assemblies PA of the present invention to the digital cameras). More specifically, FIG. 11A shows an example of application of an optical element assembly PA to the digital camera 200; and FIG. 11B shows an example of application of an optical element assembly PA to the digital camera 300.

Similar to the image pickup apparatus 100 shown in FIG. 1, the digital camera 200 shown in FIG. 11A has an image pickup optical system 210 including, for example, the optical element assembly PA, an image pickup device 220, an image data producing circuit 230, and a recorder circuit 232. In relation to the image data producing circuit 230, there are provided, for example, an image display circuit 236, and a monitoring optical system 250 to monitor images displayed on the image display circuit 236.

The digital camera 300 shown in FIG. 11B has an optical-image forming optical system 350 images an optical image suitable for image observation from a luminous flux injected from the optical element assembly PA. The optical-image forming optical system 350 has a focusing lens 351, a porro prism 352, and a viewing window 353. By way of additional members or components, reference numeral 310 denotes an image pickup optical system, numeral 320 denotes an image pickup device, and numeral 330 denotes an image data producing circuit.

In any case of FIGS. 11A and 11B, the optical system including the optical element assembly PA is configured suitably to be mounted into a housing of the digital camera 200, 300.

(Fifth Embodiment)

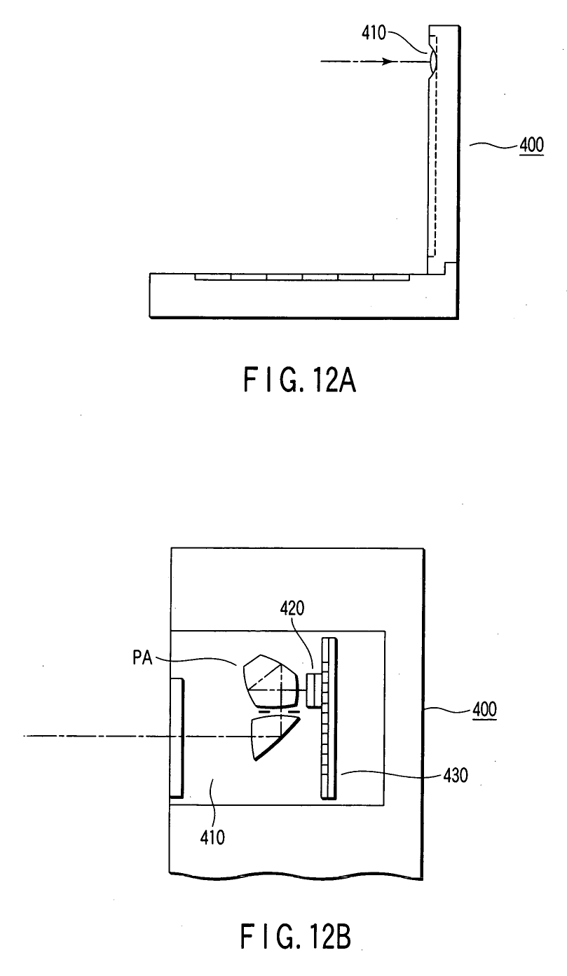

FIGS. 12A and 12B together show a schematic configuration of a personal computer (notebook personal computer) according to a fifth embodiment of the invention (an example of application of an optical element assembly PA of the present invention to the personal computer). More specifically, FIG. 12A is a side view showing a schematic configuration of the notebook personal computer; and FIG. 12B is a schematic cross-sectional view of an important portion of the configuration.

As shown in FIGS. 12A and 12B, members or components such as an image pickup optical system 410 including the optical element assembly PA, an image pickup device 420, and an image data producing circuit 430 are configured suitably to be mounted into a housing of the personal computer 400.

(Sixth Embodiment)

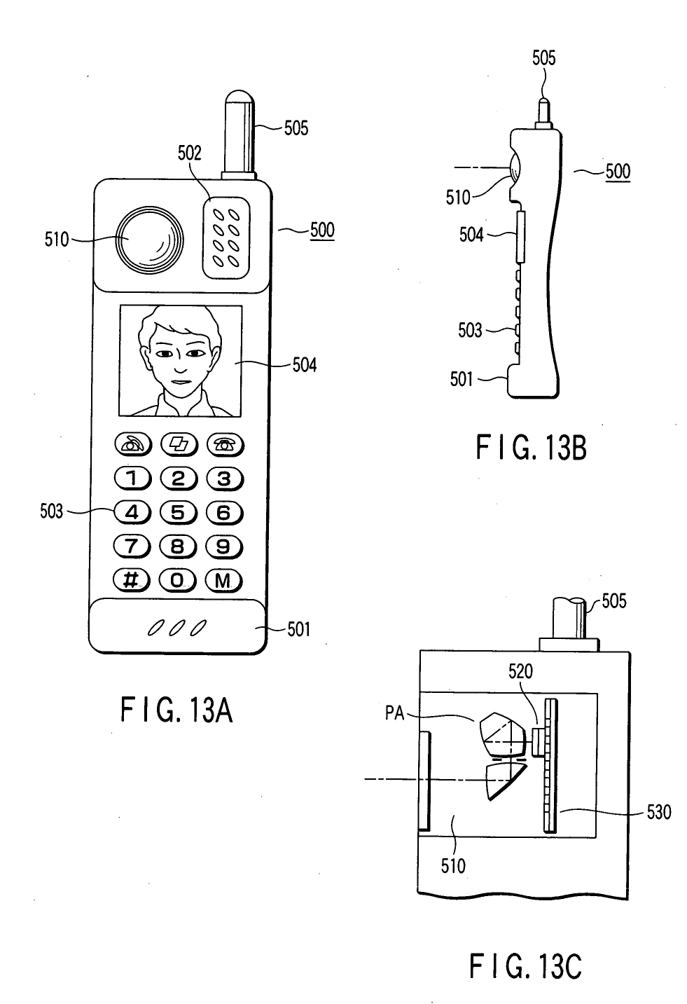

FIGS. 13A to 13C together show a schematic configuration of a mobile phone according to a sixth embodiment of the invention (an example of application of an optical element assemblies PA of the present invention to the mobile phone). More specifically, FIG. 13A is a plan view of the mobile phone 500, FIG. 13B is a side view thereof, and FIG. 13C is a schematic cross-sectional view of an important portion of the phone.

As shown in FIGS. 13A to 13C, members or components such as an image pickup optical system 510 including the optical element assembly PA, an image pickup device 520, and an image data producing circuit 530 are configured suitably to be mounted into a housing of the mobile phone 500. In the drawing, reference numeral 501 denotes a voice-input microphone, numeral 502 denotes a speaker, numeral 503 denotes input operation buttons, numeral 504 denotes a monitor display screen, and numeral 505 denotes an antenna.

(Features of the First to Sixth Embodiments)

(1) The first embodiment of the present invention is the optical element assembly PA characterized by comprising the first optical element 10 which includes the prism configured such that incident light arrived from an object and input to the first predetermined incident surface 11 is reflected by the predetermined reflecting surface 12 having power and injected from the first predetermined injection surface 13; the second optical element 20 configured such that incident light arrived from the first optical element 10 and input to the second predetermined incident surface 21 is reflected by the predetermined reflecting surfaces 22-1 and 22-2 having power and injected from the second predetermined injection surface 23; and the positioning holder member 30 for holding the first optical element 10 and the second optical element 20 which includes the prism so that relative positions of the first optical element 10 and the second optical element 20 are maintained in the predetermined relationship,

wherein the first optical element 10 has the engageably shaped portions 15a and 15b formed in the peripheral portion of the effective area 14 on the first injection surface 13 through which the effective luminous flux passes, the engageably shaped portions 15a and 15b respectively corresponding to the one engageably shaped portions 35a and 35b formed on one opponent surface 31 of the positioning holder member 30 that opposes the first injection surface 13,

wherein the second optical element 20 has the engageably shaped portions 26a and 26b formed in the peripheral portion of an effective area 24 on the second incident surface 21 through which the effective luminous flux passes, the engageably shaped portions 26a and 26b respectively corresponding to the other engageably shaped portions 36a and 36b formed on the other opponent surface 32 of the positioning holder member 30 that opposes the second incident surface 21, and

wherein the positioning holder member 30 has, formed in the predetermined portion, the optical diaphragm aperture 33 that permits transmission of light between said one opponent surface 31 and the other opponent surface 32.

(2) The optical element assembly according to the first embodiment described in item (1) is further characterized in that in the first optical element 10, the engageably shaped portions 15a and 15b are individually formed as the being protrusion portions (short columnar portions).

(3) The optical element assembly according to the first embodiment described in item (1) above is further characterized in that in the second optical element 20, the engageably shaped portions 26a and 26b are individually formed as being the protrusion portions (short columnar portions).

(4) The optical element assembly according to the first embodiment described in item (1) is further characterized in that in the positioning holder member 30, the one engageably shaped portions 35a and 35b formed on the one opponent surface 31 are individually formed as being the recess portions (circular openings).

(5) The optical element assembly according to the first embodiment described in item (1) is further characterized in that in the positioning holder member 30, the other engageably shaped portions 36a and 36b formed on the other opponent surface 32 are individually formed as being the recess portions (circular openings).

(6) The optical element assembly according to the first embodiment described in. item (1) is further characterized in that in the first optical element 10, the engageably shaped portions are individually formed as being the recess portions.

(7) The optical element assembly according to the first embodiment described in item (1) above is further characterized in that in the second optical element 20, the engageably shaped portions are individually formed as being the recess portions.

(8) The optical element assembly according to the first embodiment described in item (1) is further characterized in that in the positioning holder member 30, the one engageably shaped portions formed on the one opponent surface 31 are individually formed as being the protrusion portions.

(9) The optical element assembly according to the first embodiment described in item (1) is further characterized in that in the positioning holder member 30, the other engageably shaped portions 36a and 36b formed on the other opponent surface 32 are individually formed as being the protrusion portions.

(10) The optical element assembly according to the first embodiment described in item (1) is further characterized in that in the first optical element 10, the first posture adjustment portions 17a to 17c for adjusting the relative posture of the first optical element 10 to the positioning holder member 30 are formed in the predetermined portions on the first injection surface 13 that are segregated at the predetermined distances from the engageably shaped portions 15a and 15b and that are out of the effective area 14.

(11) The optical element assembly according to the first embodiment described in item (1) is further characterized in that in the second optical element 20, the second posture adjustment portions 27a to 27c for adjusting the relative posture of the second optical element 20 to the positioning holder member 30 are formed in predetermined portions on the second incident surface 21 that are segregated at the predetermined distances from the engageably shaped portions 26a and 26b and that are out of the effective area 24.

(12) The optical element assembly according to the first embodiment described in item (1) is further characterized in that in the positioning holder member 30, the first abutment portions 31a to 31c that respectively abut the first posture adjustment portions 17a to 17c, which are formed on the side of the first optical element 10 to adjust the relative posture thereof to the positioning holder member 30, are set in the predetermined portions of the one opponent surface 31.

(13) The optical element assembly according to the first embodiment described in item (1) is further characterized in that in the positioning holder member 30, the second abutment portions 32a to 32c that respectively abut the second posture adjustment portions 27a to 27c, which are formed on the side of the second optical element 20 to adjust the relative posture thereof to the positioning holder member 30, are set in the predetermined portions of the other opponent surface 32.

(14) The optical element assembly according to the first embodiment described in item (10) is further characterized in that the first posture adjustment portions 17a to 17c of the first optical element 10 are individually formed as being the semispherical protrusion portions.

(15) The optical element assembly according to the first embodiment described in item (11) is characterized in that the second posture adjustment portions 27a to 27c of the second optical element 20 are individually formed as being the semispherical protrusion portions.

(16) The optical element assembly according to the second embodiment is the optical element assembly described in item (11), characterized in that abutting surfaces of the first posture adjustment portions 37a to 37c provided on the positioning holder member 30 are individually formed as being the semispherical protrusion portions.

(17) The optical element assembly according to the second embodiment is the optical element assembly described in item (11) characterized in that abutting surfaces of the second posture adjustment portions 38a to 38c provided on the positioning holder member 30 are individually formed as being the semispherical protrusion portions.

(18) The optical element assembly according to the second embodiment is based on the optical element assembly described in item (1) and is characterized in that the first optical element 10 has the first-optical-element-side abutment portions 10a to 10c that respectively abut the first positioning-holder-member-side posture adjustment portions 37a to 37c which are formed on the side of the positioning holder member 30 to adjust the posture thereof with respect to the first optical element 10.

(19) The optical element assembly according to the second embodiment is based on the optical element assembly described in item (1) and is further characterized in that the first optical element 10 has the second-optical-element-side abutment portions 20a to 20c that respectively abut the second positioning-holder-member-side posture adjustment portions 38a to 38c which are formed on the side of the positioning holder member 30 to adjust the posture thereof with respect to the first optical element 10.

(20) The optical element assembly directed to the third embodiment is based on the optical element assembly described in item (1) and is characterized in that:

in the first optical element 10 and/or the second optical element 20, the engageably shaped portions are formed as being pyramidal protrusion portions 19a to 19c each formed in the shape of a pyramidal body or to include a shaped portion similar to a pyramidal body; and

in the positioning holder member 30, the engageably shaped portions are formed as being the pyramidal recess portions 39a to 39c individually formed to have shapes having surface portions engageable with the pyramidal protrusion portions 19a to 19c formed on the side of the first optical element 10 and/or the-second optical element 20 and along outer circumferential surfaces thereof.

(21) The optical element assembly according to the third embodiment is based on the optical element assembly described in item (1) and is further characterized in that:

in the first optical element 10 and/or the second optical element 20, the engageably shaped portions are individually formed as being the pyramidal recess portions in the shapes having the surface portions along outer circumferential surfaces of the pyramidal protrusion portions each formed in the predetermined pyramidal body or to include the shaped portion similar to the portion of the predetermined pyramidal body; and

in the positioning holder member 30, the engageably shaped portions are formed as being the pyramidal protrusion portions individually formed to have the shapes engageable with the pyramidal recess portions formed on the side of the first optical element 10 and/or the second optical element 20 and to have the shapes of the predetermined pyramidal bodies or shapes each including the shaped portion similar to the portion of the predetermined pyramidal body.

(22) The image pickup apparatuses (100 and 200) directed to the first and second embodiments are each characterized by comprising:

the optical element assembly PA formed to include. the first optical element 10 which includes the prism configured such that incident light arrived from an object and input to the first predetermined incident surface 11 is reflected by the predetermined reflecting surface 12 having power and injected from the first predetermined injection surface 13; the second optical element 20 which includes the prism configured such that incident light arrived from the first optical element 10 and input to the second predetermined incident surface 21 is reflected by the predetermined reflecting surfaces 22-1 and 22-2 having power and injected from the second predetermined injection surface 23; and the positioning holder member 30 for holding the first optical element 10 and the second optical element 20 so that relative positions. of the first optical element 10 and the second optical element 20 are maintained in the predetermined relationship,

wherein the first optical element 10 has the engageably shaped portions 15a and 15b formed in the peripheral portion of the effective area 14 on the first injection surface 13 through which the effective luminous flux passes, the engageably shaped portions 15a and 15b respectively corresponding to the one engageably shaped portions 35a and 35b formed on one opponent surface 31 of the positioning holder member 30 that opposes the first injection surface 13,

wherein the second optical element 20 has the engageably shaped portions 26a and 26b formed in the peripheral portion of the effective area 24 on the second incident surface 21 through which the effective luminous flux passes, the engageably shaped portions. 26a and 26b respectively corresponding to the other engageably shaped portions 36a and 36b formed on the other opponent surface 32 of the positioning holder member 30 that opposes the second incident surface 21, and

wherein the positioning holder member 30 has, formed in the predetermined portion, the optical diaphragm aperture 33 that permits transmission of light between the one opponent surface 31 and the other opponent surface 32,

the image pickup device (120, 220) adapted to perform the photoelectrical conversion of the optical image of the luminous flux injected from the predetermined injection surface 23 of the optical element assembly PA; and

the image data producing circuit (130, 230) adaptable to the predetermined recording and/or communication in accordance with the output signal of the image pickup device (120, 220).

(23) The image pickup apparatuses 300 directed to the third embodiment are each characterized by comprising:

the optical element assembly PA formed to include the first optical element 10 which includes a prism configured such that incident light arrived from the side of an object and input to the first predetermined incident surface 11 is reflected by the first predetermined reflecting surface having power and injected from the first predetermined injection surface 13; the second optical element 20 which includes the prism configured such that incident light arrived from the first optical element 10 and input to the second predetermined incident surface 21 is reflected by the predetermined reflecting surfaces 22-1 and 22-2 having power and injected from the second predetermined injection surface 23; and the positioning holder member 30 for holding the first optical element 10 and the second optical element 20 so that relative positions of the first optical element 10 and the second optical element 20 are maintained in the predetermined relationship, wherein

the first optical element 10 has the engageably shaped portions 15a and 15b formed in the peripheral portion of the effective area 14 on the first injection surface 13 through which the effective luminous flux passes, the engageably shaped portions 15a and 15b respectively corresponding to the first engageably shaped portions 35a and 35b formed on one opponent surface 31 of the positioning holder member 30 that opposes the first injection surface 13; wherein the second optical element 20 has the engageably shaped portions 26a and 26b formed in the peripheral portion of the effective area 24 on the second incident surface 21 through which the effective luminous flux passes, the engageably shaped portions 26a and 26b respectively corresponding to the second engageably shaped portions 36a and 36b formed on the other opponent surface 32 of the positioning holder member 30 that opposes the second incident surface 21; and wherein the positioning holder member 30 has, formed in the predetermined portion, the optical diaphragm aperture 33 that permits transmission of light between the one opponent surface 31 and the other opponent surface 32; and

the optical-image forming optical system 350 for imaging an optical image suitable for image observation from a luminous flux injected from the second predetermined injection surface 23 of the second optical element 20 of the optical element assembly PA.

(24) The image pickup apparatus according to the fourth embodiment described in item (22) is further characterized in that the optical element assembly PA, the image pickup device 210, and the image data producing circuit 230 are configured suitably to be mounted into the housing of the digital camera 200.

(25) The image pickup apparatus directed to the fifth embodiment is based on the image pickup apparatus described in item (22) and is characterized in that the optical element assembly PA, the image pickup device 210, and the image data producing circuit 230 are configured suitably to be mounted into the housing of the personal computer 400.

(26) The image pickup apparatus directed to the sixth embodiment is based on the image pickup apparatus described in item (22) is characterized in that the optical element assembly PA, the image pickup device 210, and the image data producing circuit 230 are configured suitably to be mounted into the housing of the mobile phone 500.

(Modified Examples)

The optical element assemblies and the image pickup apparatuses according to the individual embodiments include the following types of modified examples:

(1) Modified example wherein the engageably shaped portions of the first optical element 10 and/or the second optical element 20 are individually formed as being the recess portions;

(2) Modified example wherein the engageably shaped portions formed on the one opponent surface 31 and/or the other opponent surface 32 of the positioning holder member 30 are individually formed as being the protrusion portions;

(3) Modified example wherein the engageably shaped portions formed on the one opponent surface 31 and/or the other opponent surface 32 of the positioning holder member 30 are individually formed as being the pyramidal recess portions; and

(4) Modified example wherein the engageably shaped portions formed on the one opponent surface 31 and/or the other opponent surface 32 of the positioning holder member 30 are individually formed as being the pyramidal protrusion portions.

Application of the present invention thus directed to each of the above-described first to sixth embodiments and the modified examples thereof enables extremely steady provision of the optical element assembly and the image pickup apparatus using the assembly that are required to be miniaturized and thinned.

(Seventh Embodiment)

A seventh embodiment will now be described hereunder. Basic configurations of an optical element assembly PA and an image pickup apparatus 100 employing the optical element assembly PA in accordance with the seventh embodiment are similar to those shown in FIGS. 1 to 5 of the optical element assembly PA and the image pickup apparatus 100 employing the optical element assembly PA in accordance with the first embodiment.

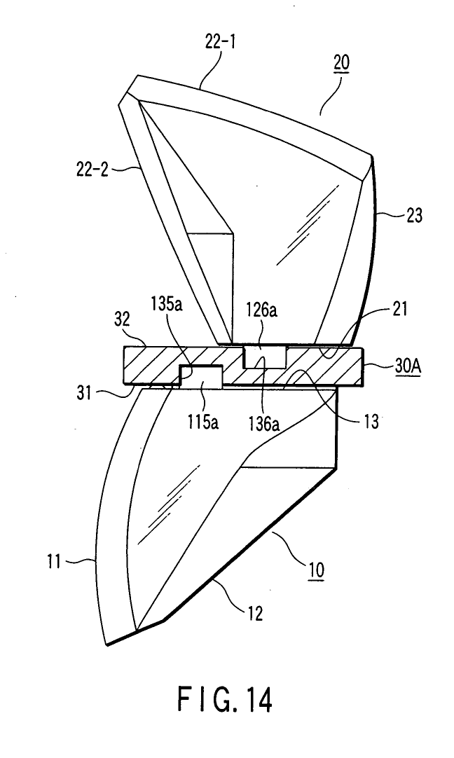

FIG. 14 is a side view cutaway of the configuration having a connection relationship between a luminous flux injection surface of the first optical element 10, the second optical element 20, and both sides of a positioning holder member 30A (corresponding to the positioning holder member 30 in the first embodiment) in the optical element assembly PA according to the seventh embodiment of the present invention.

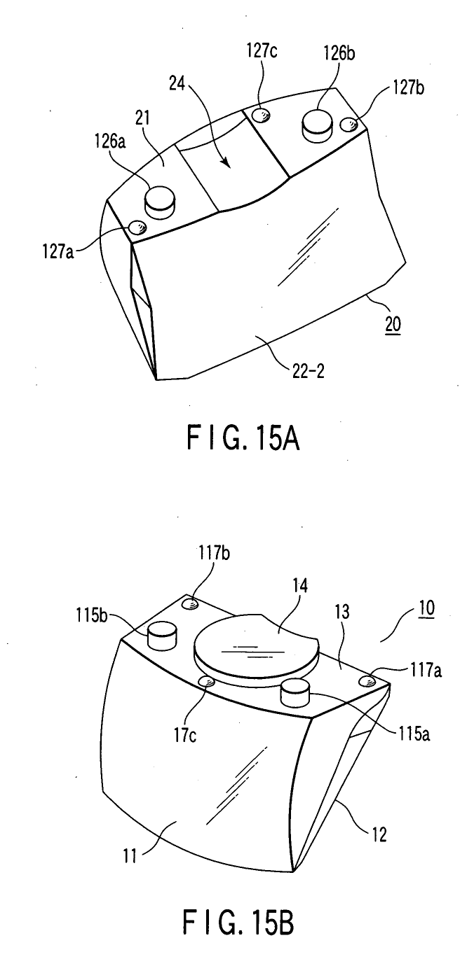

FIGS. 15A and 15B are, respectively, perspective views showing the structures of the luminous flux injection surface of the first optical element 10 and the luminous flux incident surface of the second. optical element 20 of in the optical element assembly (PA) according to the seventh embodiment of the present invention.

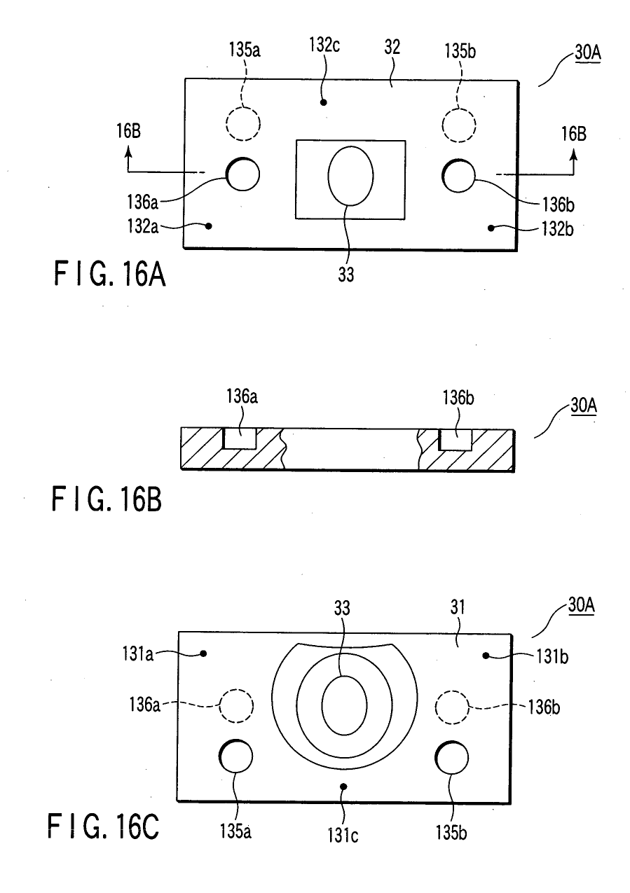

FIGS. 16A to 16C show the structure of the positioning holder member of the optical element assembly (PA) according to the seventh embodiment of the present invention. More specifically, FIG. 16A is a plan view showing the shape of a surface of the positioning holder member 30A; FIG. 16B is a cross-sectional view taken along a line 16B-16B; and FIG. 16C is a plan view showing the reverse side of the positioning holder member 30A.

With reference to FIGS. 3 to 5 (used above), 14, and 16A to 16C, the first optical element 10 of the optical element assembly PA according to the seventh embodiment of the invention has engageable protrusion portions 115a and 115b (corresponding to the engageably shaped portions 15a and 15b in the first embodiment) formed of short circularly-columnar protrusion portions in a peripheral portion of an effective area 14 on a first injection surface 13 through which the effective luminous flux passes. The respective engageable protrusion portions 15a and 115b engage engageable recess portions 135a and 135b (corresponding to the engageably shaped portions 35a and 35b in the first embodiment) formed on the one opponent surface 31 of the positioning holder member 30A that opposes the injection surface 13 of the first optical element 10. The second optical element 20 has engageable protrusion portions 126a and 126b (corresponding to the engageably shaped portions 26a and 26b in the first embodiment) formed of short circularly-columnar protrusion portions in a peripheral portion of an effective area 24 on the side of a second incident surface 21 through which the effective luminous flux passes. The respective engageable protrusion portions 126a and 126b engage engageable recess portions 136a and 136b (corresponding to the engageably shaped portions 36a and 36b in the first embodiment) formed on the other opponent surface 32 of the positioning holder member 30A that opposes the second incident surface 21 of the second optical element 20.

In the seventh embodiment, the positioning holder member 30A is formed of a material having optical-shield properties. The positioning holder member 30A has in a substantially central portion thereof an optical diaphragm aperture 33 that permits transmission of the luminous flux between the one opponent surface 31 and the other opponent surface 32. The aperture 33 is a practical example of the functional section 301 as being the optical diaphragm already described in conjunction with FIG. 2. In addition, the positioning holder member 30A has on the one opponent surface 31 the engageable recess portions 135a and 135b (bottomed), and similarly has on the other opponent surface 32 the engageable recess portions 136a and 136b (bottomed).

The engageable protrusion portions 115a and 115b of the first optical element 10 are engaged with the engageable recess portions 135a and 135b of the positioning holder member 30A. Concurrently, the engageable protrusion portions 126a and 126b of the second optical element 20 are engaged with the other engageable recess portions 136a and 136b of the positioning holder member 30A. Thereby, the first optical element 10 and the second optical element 20 are integrally connected through the positioning holder member 30A being interposed therebetween to have a predetermined positional relationship.

Reference is now made to FIGS. 15A and 15B. As shown therein, first posture adjustment portions 117a to 117c each formed of a semispherical protrusion portion are formed in predetermined portions on the first injection surface 13 that are segregated at predetermined distances from the engageable protrusion portions 115a and 115b in the first optical element 10 and that are out of the effective area 14. The adjustment portions 117a to 117c are pre-adjusted in height to adjust an opposite-surface tilt angle of the first injection surface 13 of the first optical element 10 to the one opponent surface 31 of the positioning holder member 30A, whereby to perform the posture adjustment.

In addition, second posture adjustment portions 127a to 127c, individually formed of semispherical protrusion portions, are formed in predetermined portions on the second incident surface 21 that are segregated at predetermined distances from the engageable protrusion portions 126a and 126b of the second optical element 20 and that are out of the effective area 24. The second posture adjustment portions 127a to ¹27c are pre-adjusted in height to adjust an opposite-surface tilt angle of the incident surface 21 of the second optical element 20 to the other opponent surface 32 of the positioning holder member 30A, whereby to perform the posture adjustment.

With reference to FIGS. 16A to 16C, first abutment portions 131a to 131c to abut the respective first posture adjustment portions 117a to 117c, formed in the first optical element 10 are set in predetermined portions of the one opponent surface 31 of the positioning holder member 30A.

In addition, second abutment portions 132a to 132c to abut the respective second posture adjustment portions 127a to 127c formed in the second optical element 20 are set in predetermined portions of the other opponent surface 32 of the positioning holder member 30A.

The respective first posture adjustment portions and the second posture adjustment portions may be provided on the positioning holder member 30A, not on the first optical element 10 and second optical element 20.

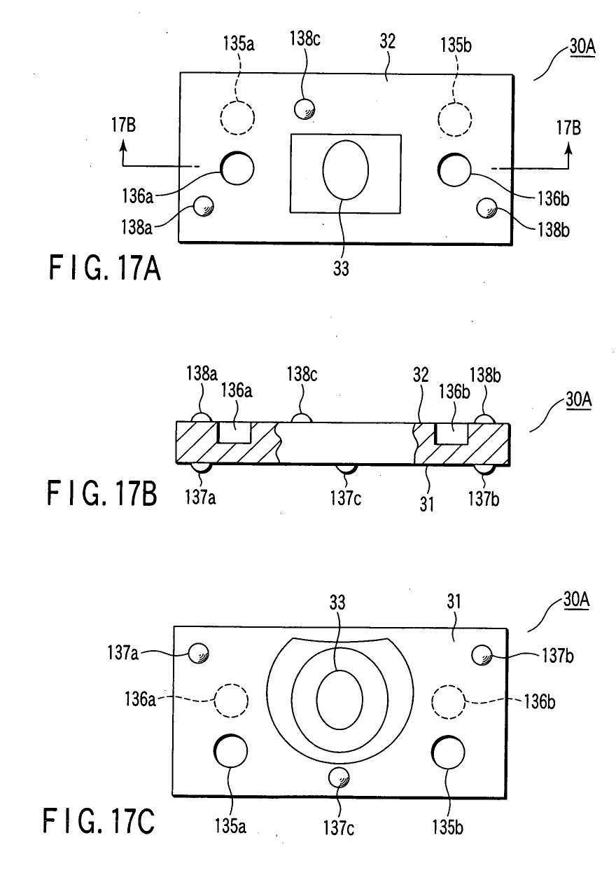

In this connection, FIGS. 17A to 17C are, respectively, views corresponding to FIGS. 15A to 15C and show a modified example of the positioning holder member 30A. More specifically, FIG. 17A is a plan view showing the shape of the surface of the positioning holder member 30A (modified); FIG. 17B is a cross-sectional view taken along a line 17B-17B of FIG. 17A; and FIG. 17C is a plan view showing the reverse side of the positioning holder member 30A.

As shown in FIGS. 17A to 17C, first positioning-holder-member-side posture adjustment portions 137a to 137c, each of which is formed of a semispherical protrusion portion, are formed on the one opponent surface 31 of the positioning holder member 30A. In addition, second positioning-holder-member-side posture adjustment portions 138a to 138c, each of which is formed of a semispherical protrusion portion, are formed on the other opponent surface 32 of the positioning holder member 30A.

As described above, the positioning holder member 30A of the present invention is formed of the optical-shield material. Additionally, the engageable recess portions 135a and 135b and the engageable recess portions 136a and 136b, which are respectively engageable with the engageable protrusion portions 115a and 115b of the first optical element 10 and the engageable protrusion portions 126a and 126b of the second optical element 20, are individually formed as being the bottomed circular openings. As such, unnecessary light can be securely prevented from traveling between the first optical element 10 and the second optical element 20 through positioning holder member 30A. Consequently, the optical element assembly PA can be prevented from being inversely effected by such unnecessary light.

(Eighth Embodiment)

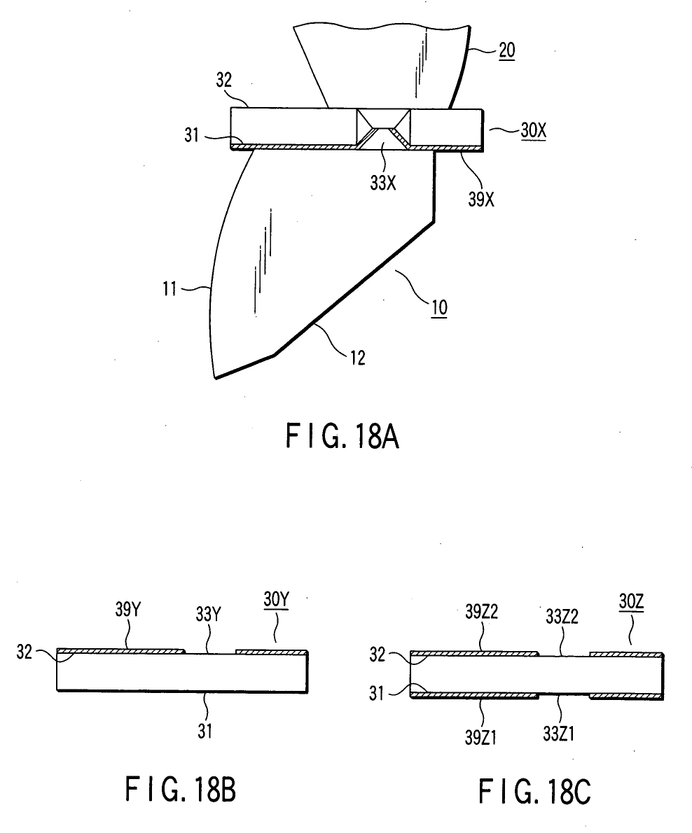

FIGS. 18A to 18C show the configuration of an optical element assembly according to an eighth embodiment of the present invention. More specifically, FIG. 18A being a cross-sectional view of a major portion of the configuration; and FIGS. 18B and 18C are cross-sectional views individually showing modified examples of the positioning holder member. The eighth embodiment is different from the seventh embodiment in that an optical-shield film is formed in a predetermined portion of member outer surfaces to impart optical-shield functionality to the positioning holder member.

Specifically, as shown in FIG. 18A, while a positioning holder member 30X in the present embodiment is formed using a transparent member, an optical-shield film 39X is formed in such a manner as adhesion or coating on the one opponent surface 31 except for a portion where an optical diaphragm aperture 33X is formed. As in an example shown in FIG. 18B, the optical-shield film may be formed on the other opponent surface 32. More specifically, an optical-shield film 39Y is adhesively formed on the other opponent surface 32 except for a portion where an optical diaphragm aperture 33Y is formed. By way of another example, as shown in FIG. 18C, optical-shield films may be formed on both surfaces 31 and 32 of the holder member 30X. Specifically, optical-shield films 39Z1 and 39Z2 are adhesively formed on both surfaces 31 and 32 of the holder member 30X except for portions where optical diaphragm apertures 33Z1 and 33Z2 are formed.

(Ninth Embodiment)

A ninth embodiment of the present invention may be an application example wherein the optical element assembly PA according to any one of the seventh and eighth embodiments be applied to a digital camera of the type shown in FIGS. 11A and 11B.

(Tenth Embodiment)

A tenth embodiment of the present invention may be an application example wherein the optical element assembly PA according to any one of the seventh and eighth embodiments be applied to a personal computer of the type shown in FIGS. 12A and 12B.

(Eleventh Embodiment)

An eleventh embodiment of the present invention may be an application example wherein the optical element assembly PA according to any one of the seventh and eighth embodiments be applied to a mobile phone of the type shown in FIGS. 13A to 13C.

(Features of the Seventh to Eleventh Embodiments)

(1) The optical element assembly according to the seventh embodiment is the optical element assembly PA characterized by comprising the first optical element 10 which includes the prism configured such that incident light arrived from an object and input to the first predetermined incident surface 11 is reflected by the predetermined reflecting surface 12 having power and injected from the first predetermined injection surface 13; the second optical element 20 which includes the prism configured such that incident light arrived from the first optical element 10 and input to the second predetermined incident surface 21 is reflected by the predetermined reflecting surfaces 22-1 and 22-2 having power and injected from the second predetermined injection surface 23; and the positioning holder member 30A for holding the first optical element 10 and the second optical element 20 so that relative positions of the first optical element 10 and the second optical element 20 are maintained in a predetermined relationship,

wherein the first optical element 10 has the engageable protrusion portions 115a and 115b formed in the peripheral portion of the effective area 14 on the first injection surface 13 through which the effective luminous flux passes, the engageable protrusion portions 115a and 115b being provided to engage one opponent surface 31 of the positioning holder member 30A that opposes the first injection surface 13,

wherein the second optical element 20 has the engageable protrusion portions 126a and 126b formed in the peripheral portion of the effective area 24 on the second incident surface 21 through which the effective luminous flux passes, the engageable protrusion portions 126a and 126b being provided to engage the other opponent surface 32 of the positioning holder member 30A that opposes the second incident surface 21, and

the positioning holder member 130 has, formed in the predetermined portion, the optical diaphragm aperture 33 that permits transmission of light between the one opponent surface 31 and the other opponent surface 32, and additionally has, respectively on the one opponent surface 31 and the other opponent surface 32, the engageable recess portions 135a and 135b that are formed to respectively correspond to and to be engageable with the engageable protrusion portions 115a and 115b of the first optical element 10 and the engageable protrusion portions 126a and 126b of the second optical element 20.

(2) The optical element assembly according to item (1) is further characterized in that positioning holder member 130 is formed of the optical-shield material.

(3) The optical element assembly according the eighth embodiment is based on the optical element assembly described in item (1) and is characterized in that the positioning holder member 30X comprises the optical-shield film formed on the predetermined portion of the outer surface of its own.

(4) The image pickup apparatus according to the ninth embodiment is characterized by comprising the optical element assembly PA formed to include the first optical element 10 which includes the prism configured such that incident light arrived from an object and input to the first predetermined incident surface 11 is reflected by the predetermined reflecting surface 12 having power and injected from the first predetermined injection surface 13; the second optical element 20 which includes the prism configured such that incident light arrived from the first optical element 10 and input to the second predetermined incident surface 21 is reflected by the predetermined reflecting surfaces 22-1 and 22-2 having power and injected from the predetermined injection surface 23; and the positioning holder member 130 for holding the first optical element 10 and the second optical element 20 so that relative positions of the first optical element 10 and the second optical element 20 are maintained in the predetermined relationship,

wherein the first optical element 10 has the engageable protrusion portions 115a and 115b formed in the peripheral portion of the effective area 14 on the first injection surface 13 through which the effective luminous flux passes, the engageable protrusion portions 115a and 115b being provided to engage one opponent surface 31 of the positioning holder member 30A that opposes the first injection surface 13,

wherein the second optical element 20 has the engageable protrusion portions 126a and 126b formed in the peripheral portion of the effective area 24 on the second incident surface 21 through which the effective luminous flux passes, the engageable protrusion portions 126a and 126b being provided to engage the other opponent surface 32 of the positioning holder member 30A that opposes the incident surface 21,

wherein the positioning holder member 30A comprises has, formed in the predetermined portion, the optical diaphragm aperture 33 that permits transmission of light between the one opponent surface 31 and the other opponent surface 32, and additionally comprises, respectively on the one opponent surface 31 and the other opponent surface, the engageable recess portions 135a and 135b that are formed to respectively correspond to and to be engageable with the engageable protrusion portions 115a and 115b of the first optical element 10 and the engageable protrusion portions 126a and 126b of the second optical element 20, and

the image pickup device 220 adapted to perform the photoelectrical conversion of the optical image of the luminous flux injected from the predetermined injection surface 23 of the optical element assembly PA; and

the image data producing circuit 230 adaptable to the predetermined recording and/or communication in accordance with the output signal of the image pickup device 220.

(5) The image pickup apparatus according to the ninth embodiment is characterized by comprising the optical element assembly PA formed to include the first optical element 10 which includes the prism configured such that incident light arrived from an object and input to a first predetermined incident surface 11 is reflected by the predetermined reflecting surface having power having power and injected from the second predetermined injection surface 13; the second optical element 20 which includes the prism configured such that incident light arrived from the first optical element 10 and input to the second predetermined incident surface 21 is reflected by the predetermined reflecting surfaces 22-1 and 22-2 having power and injected from the second predetermined injection surface 23; and the positioning holder member 30A for holding the first optical element 10 and the second optical element 20 so that relative positions of the first optical element 10 and the second optical element 20 are maintained in the predetermined relationship,

wherein the first optical element 10 has the engageable protrusion portions 115a and 115b formed in the peripheral portion of the effective area 14 on the first injection surface 13 through which the effective luminous flux passes, the engageable protrusion portions 115a and 115b being provided to engage one opponent surface 31 of the positioning holder member 30A that opposes the first injection surface 13,

wherein the second optical element 20 has the engageable protrusion portions 126a and 126b formed in the peripheral portion of the effective area 24 on the second incident surface 21 through which the effective luminous flux passes, the engageable protrusion portions 126a and 126b being provided to engage the other opponent surface 32 of the positioning holder member 30A that opposes the second incident surface 21,

wherein the positioning holder member 30A has, formed in the predetermined portion, the optical diaphragm aperture 33 that permits transmission of light between the one opponent surface 31 and the other opponent surface 32, and additionally comprises, respectively on the one opponent surface 31 and the other opponent surface, the engageable recess portions 135a and 135b that are formed to respectively correspond to and to be engageable with the engageable protrusion portions 115a and 115b of the first optical element 10 and the engageable protrusion portions 126a and 126b of the second optical element 20, and

the optical-image forming optical system 350 for imaging the optical image suitable for the image observation from the luminous flux injected from the second predetermined injection surface 23 of the second optical element 20 of the optical element assembly PA.

(6) The image pickup apparatus according to the ninth embodiment described in item (4) is further characterized in that the optical element assembly PA, the image pickup device 210, and the image data producing circuit 230 are configured suitably to be mounted into the housing of the digital camera 200.

(7) The image pickup apparatus directed to the tenth embodiment is based on the image pickup apparatus described in item (4) is characterized in that the optical element assembly PA, the image pickup device 210, and the image data producing circuit 230 are configured suitably to be mounted into the housing of the personal computer 400.

(8) The image pickup apparatus directed to the eleventh embodiment is based on the image pickup apparatus described in item (4) and is characterized in that the optical element assembly PA, the image pickup device 210, and the image data producing circuit 230. are configured suitably to be mounted into the housing of the mobile phone 500.

Application of the present invention thus directed to each of the above-described seventh to twelfth embodiments and the modified examples thereof enables extremely steady provision of the optical element assembly and the image pickup apparatus using the assembly that are required to be miniaturized and thinned.

(Twelfth Embodiment)

A twelfth embodiment of the present invention will now be described hereunder. Basic configurations of an optical element assembly PA and an image pickup apparatus 100 employing the optical element assembly PA in accordance with the twelfth embodiment are similar to those shown in FIGS. 1 to 5 of the optical element assembly PA and the image pickup apparatus 100 employing the optical element assembly PA in accordance with the first embodiment.

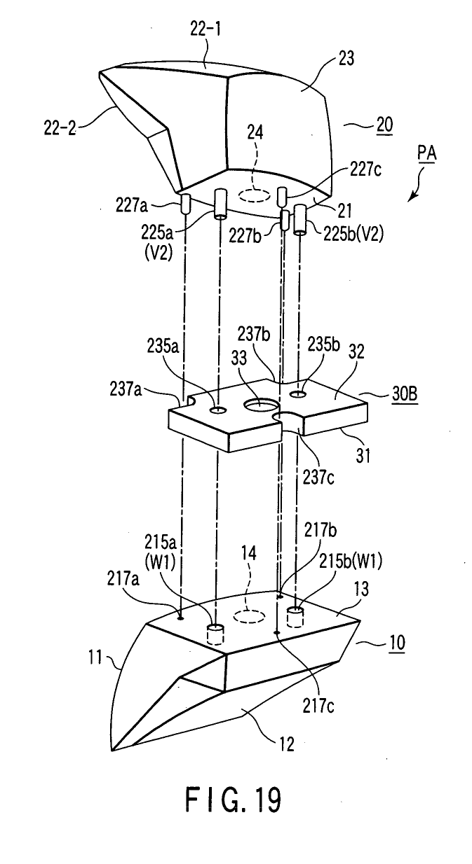

FIG. 19 is an exploded perspective view showing the state where a first optical element, a second optical element, and a diaphragm member 30B of the optical element assembly according to the twelfth embodiment of the invention are disconnected from one another.

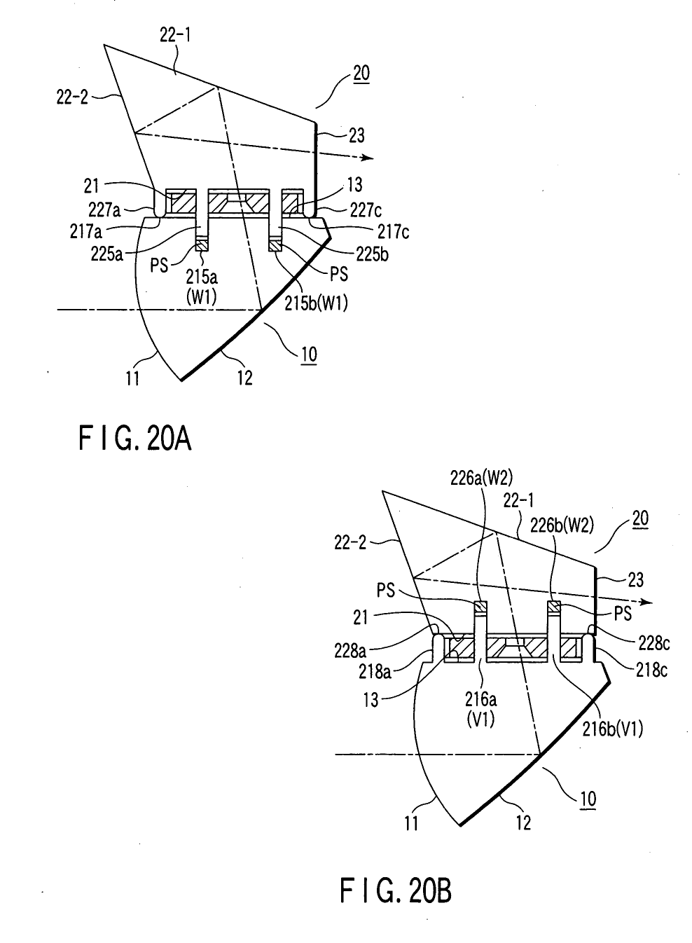

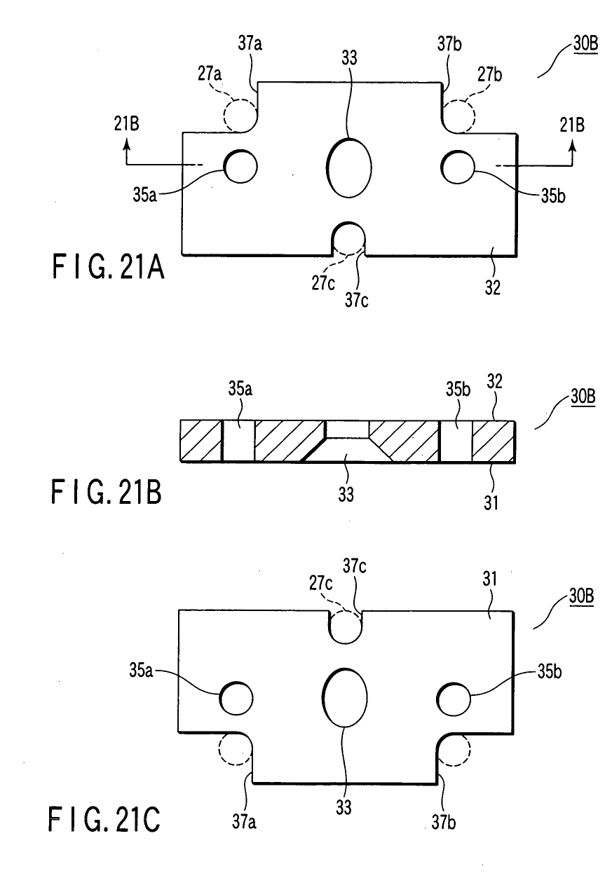

FIG. 20A is a cross-sectional view showing the state where the first optical element 10 and second optical element 20 of the optical element assembly are integrally held through the diaphragm member 30B. FIG. 20B is a cross-sectional view showing a partially modified example of the assembly of FIG. 20A. FIGS. 21A to 21C show the structure of the diaphragm member 30B of the optical element assembly according to the twelfth embodiment of the invention; FIG. 21A is a plan view showing the shape of the obverse side of the diaphragm member 30B used in the twelfth embodiment, FIG. 21B is a cross-sectional view taken along a line 21B-21B of FIG. 21A; and FIG. 21C is a plan view showing the shaping of the reverse side of the diaphragm member 30B.

With reference to FIGS. 19 to 21A to 21C, the first optical element 10 has engageably shaped portions 215a and 215b individually formed of circularly cylindrical recess portions W1 in a peripheral portion of the effective area 14 on the first injection surface 13 through which an effective luminous flux passes. The engageably shaped portions 215a and 215b are formed to respectively correspond to the one engageably shaped portions 225a and 225b formed in a peripheral portion of the effective area 24 on the second incident surface 21 of the second optical element 20 through which the effective luminous flux passes. The second optical element 20 has the one engageably shaped portions 225a and 225b in the peripheral portion of the effective area 24 on the second incident surface 21, and the one engageably shaped portions 225a and 225b are individually formed of circularly columnar protrusion portions V2. Specifically, the one engageably shaped portions 225a and 225b are provided to respectively corresponding to and to be engageable with the engageably shaped portions 215a and 215b provided in the peripheral portion of the effective area 14, through which the effective luminous flux passes, on the first injection surface 13 of the first optical element 10.

Posture adjustment portions 227a to 227c are formed in predetermined portions on the second incident surface 21 that are segregated at predetermined distances from the one engageably shaped portions 225a and 225b of the second optical element 20 and that are out of the effective area 24. The posture adjustment portions 227a to 227c are each formed of a circularly columnar protrusion portion to adjust the relative posture to the first optical element 10. Specifically, the posture adjustment portions 227a to 227c are pre-adjusted in height to adjust an opposite-surface tilt angle to the first injection surface 13 of the first optical element 10, thereby performing the posture adjustment with respect to the first optical element 10.

In addition, abutment portions 217a to 217c to abut the respective posture adjustment portions 227a to 227c formed in the second optical element 20 are set in predetermined portions of the first injection surface 13 of the first optical element 10.

The diaphragm member 30B has in its substantially center portion an optical diaphragm aperture 33 that permits transmission of the luminous flux from the one opponent surface 31 to the other opponent surface 32. In addition, on both sides of the optical diaphragm aperture 33, the diaphragm member 30B has through-holes 235a and 235b that permits passing-through of the respective the one engageably shaped portions 225a and 225b of the second optical element 20. The diaphragm member 30B further has in its peripheral portion cutout portions 237a to 237c that permit passing-through the respective posture adjustment portions 227a to 227c.

With reference to FIG. 20A, shield materials PS are individually provided in predetermined regions including recessed bottom portions and the vicinities thereof inside the engageably shaped portions 215a and 215b, which are individually formed of. the recess portions W1, of the first optical element 10.

In assembly of the optical element assembly PA of the present embodiment, the circularly columnar one engageably shaped portions 225a and 225b of the second optical element 20 are inserted into the engageably shaped portions 215a and 215b of the first optical element 10 which are individually formed of the recess portions W1 through the respective through-holes 235a and 235b. Concurrently, the posture adjustment portions 227a to 227c of the second optical element 20 are, respectively, brought into abutment with the abutment portions 217a to 217c of the first optical element 10 through the cutout portions 237a to 237c of the diaphragm member 30B. In this manner, the first optical element 10 and the second optical element 20 are integrally connected with the diaphragm member 30B being interposed therebetween to have a predetermined positional relationship. In this case, since the shield materials PS are inserted inside the engageably shaped portions 215a and 215b individually formed of the portions W1, detrimental light is prevented from being transmitted between the first optical element 10 and the second optical element 20 through the one engageably shaped portions 225a and 225b.

The configuration may be formed as shown in FIG. 20B. In this configuration, engageably shaped portions 216a and 216b individually formed of protrusion portions V1 and circularly columnar posture adjustment portions 218a to 218c are provided on the first injection surface 13 of the first optical element 10. In addition, on the second incident surface 21 of the second optical element 20, there are provided engageably shaped portions 226a and 226b individually formed of recess portions W2 to respectively correspond to the engageably shaped portions 216a and 216b, and abutment portions 228a to 228c that abut the respective posture adjustment portions 218a to 218c.

(Thirteenth Embodiment)

A thirteenth embodiment of the present invention may be an application example wherein the optical element assembly PA according to the twelfth embodiment be applied to a digital camera of the type shown in FIGS. 11A and 11B.

(Fourteenth Embodiment)

A fourteenth embodiment of the present invention may be an application example wherein the optical element assembly PA according to the twelfth embodiment be applied to a personal computer of the type shown in FIGS. 12A and 12B.

(Fifteenth Embodiment)

A fifteenth embodiment of the present invention may be an application example wherein the optical element assembly PA according to the twelfth embodiment be applied to a mobile phone of the type shown in FIGS. 13A to 13C.

(Features of the Twelfth to Fifteenth Embodiments)

(1) The twelfth embodiment of the present invention is the optical element assembly PA characterized by comprising the first optical element 10 which includes the prism configured such that incident light arrived from an object and input to the first predetermined incident surface 11 is reflected by the predetermined reflecting surface 12 having power and injected from the first predetermined injection surface 13; the second optical element 20 which includes the prism configured such that incident light arrived from the first optical element 10 and input to the second predetermined incident surface 21 is reflected by the predetermined reflecting surfaces 22-1 and 22-2 having power and injected from the second predetermined injection surface 23; and the diaphragm member 30B interposed in the predetermined position between the first optical element 10 and the second optical element 20, wherein the first optical element 10 and the second optical element 20 are connected to each other so that relative positions of the first optical element 10 and the second optical element 20 are maintained in the predetermined relationship,

wherein the first optical element 10 has the engageably shaped portions 215a and 215b formed in the peripheral portion of the effective area 14 on the first injection surface 13 through which the effective luminous flux passes, the engageably shaped portions 215a and 215b respectively corresponding to one engageably shaped portions 225a and 225b formed in the peripheral portion of the effective area 24 on the second incident surface 21 of the second optical element 20 through which the effective luminous flux passes,

wherein the second optical element 20 has the engageably shaped portions 225a and 225b formed in the peripheral portion of the effective area 24 on the second incident surface 21 through which the effective luminous flux passes, the engageably shaped portions 225a and 225b respectively corresponding to the engageably shaped portions 215a and 215b provided in the peripheral portion of the effective area 14, through which the effective luminous flux passes, on the first injection surface 13 of the first optical element 10, and

wherein the diaphragm member 30B has, formed in the predetermined portion, the optical diaphragm aperture 33 that permits transmission of the luminous flux from the first injection surface 13 of the first optical element 10 to the second incident surface 21 of the second optical element 20.

(2) The optical element assembly according to the twelfth embodiment described in item (1) is further characterized in that in the first optical element 10, the engageably shaped portions 215a and 215b are individually formed as being the recess portions W1.

(3) The optical element assembly according to the twelfth embodiment described in item (1) is further characterized in that in the second optical element 20, the engageably shaped portions 225a and 225b are individually formed as being the protrusion portions V2.

(4) The optical element assembly according to the twelfth embodiment described in item (1) is further characterized in that in the first optical element 10, the engageably shaped portions 216a and 216b are individually formed as being the protrusion portions V1.

(5) The optical element assembly according to the twelfth embodiment described in item (1) is further characterized in that in the second optical element 20, the engageably shaped portions 226a and 226b are individually formed as being the recess portions W2.

(6) The optical element assembly according to the twelfth embodiment described in item (2) is further characterized in that in the recess portions W1, the shield materials PS are individually provided in the predetermined regions including the recessed bottom portions and the vicinities thereof.

(7) The optical element assembly according to the twelfth embodiment described in item (3) is further characterized in that in the protrusion portions V2 of the second optical element 20, the shield materials PS are individually provided in predetermined regions including protrusion ends portions and the vicinities thereof.

(8) The optical element assembly according to the twelfth embodiment described in item (4) is further characterized in that in the protrusion portions V1 of the first optical element 10, the shield materials PS are individually provided in predetermined regions including protrusion ends portions and the vicinities thereof.

(9) The optical element assembly according to the twelfth embodiment described in item (5) is further characterized in that in the recess portions W2 of the second optical element 20, the shield materials PS are individually provided in predetermined regions including recessed bottom portions and the vicinities thereof.

(10) The optical element assembly according to the twelfth embodiment described in item (1) is further characterized in that in the first optical element 10, the posture adjustment portions 227a to 227c for adjusting the relative posture to the second optical element 20 are formed in the predetermined portions on the second incident surface 21 that are segregated at the predetermined distances from the engageably shaped portions 225a and 225b of the second optical element 20 and that are out of the effective area 24.

(11) The optical element assembly according to the twelfth embodiment described in item (1) is further characterized in that in the first optical element 10, the posture adjustment portions 218a to 218c for adjusting the relative posture to the second optical element 20 are formed in the predetermined portions on the first injection surface 13 that are segregated at the predetermined distances from the engageably shaped portions 216a and 216b and that are out of the effective area 14.

(12) The optical element assembly according to the twelfth embodiment described in item (10) or (11) is further characterized in that the posture adjustment portions are individually formed as being the protrusion portions.

(13) The optical element assembly according to the twelfth embodiment described in item (1) is further characterized in that in the first optical element 10, abutment portions 217a to 217c to abut the respective posture adjustment portions 227a to 227c formed on the second optical element 20 to adjust the posture relative to the relative position are individually set in the predetermined portions on the first injection surface 13.

(14) The optical element assembly according to the twelfth embodiment described in item (1) is further characterized in that in the second optical element 20, abutment portions 228a to 228c to abut the respective posture adjustment portions 218a to 218c formed on the first optical element 10 to adjust the posture relative to the relative position are individually set in the predetermined portions on the second incident surface 21.

(15) The image pickup apparatus directed to the twelfth embodiment comprises the optical element assembly PA characterized by comprising the first optical element 10 which includes the prism configured such that incident light arrived from an object and input to the first predetermined incident surface 11 is reflected by the predetermined reflecting surface 12 having power and injected from the second predetermined injection surface 13; the second optical element 20 which includes the prism configured such that incident light arrived from the first optical element 10 and input to the second predetermined incident surface 21 is reflected by the predetermined reflecting surfaces 22-1 and 22-2 having power and injected from the second predetermined injection surface 23; and the diaphragm member 30B interposed in the predetermined position between the first optical element 10 and the second optical element 20, wherein the first optical element 10 and the second optical element 20 are connected to each other so that relative positions of the first optical element 10 and the second optical element 20 are maintained in the predetermined relationship,

wherein the first optical element 10 has the engageably shaped portions 215a and 215b formed in the peripheral portion of the effective area 14 on the first injection surface 13 through which the effective luminous flux passes, the engageably shaped portions 215a and 215b respectively corresponding to engageably shaped portions 225a and 225b formed in the peripheral portion of the effective area 24 on the second incident surface 21 of the second optical element 20 through which the effective luminous flux passes,

wherein the second optical element 20 has the engageably shaped portions 225a and 225b formed in the peripheral portion of the effective area 24 on the second incident surface 21 through which the effective luminous flux passes, the one engageably shaped portions 225a and 225b respectively corresponding to the engageably shaped portions 215a and 215b provided in the peripheral portion of the effective area 14, through which the effective luminous flux passes, on the first injection surface 13 of the first optical element 10, and

wherein the diaphragm member 30B has, formed in the predetermined portion, the optical diaphragm aperture 33 that permits transmission of the luminous flux from the first injection surface 13 of the first optical element 10 to the second incident surface 21 of the second optical element 20, and the image pickup device 220 adapted to perform the photoelectrical conversion of the optical image of the luminous flux injected from the predetermined injection surface 23 of the optical element assembly PA; and

the image data producing circuit 230 adaptable to the predetermined recording and/or communication in accordance with the output signal of the image pickup device 220.

(16) The image pickup apparatus directed to the twelfth embodiment comprises the optical element assembly PA characterized by comprising the first optical element 10 which includes the prism configured such that incident light arrived from an object and input to the first predetermined incident surface 11 is reflected by the predetermined reflecting surface 12 having power and injected from the first predetermined injection surface 13; the second optical element 20 which includes the prism configured such that incident light arrived from the first optical element 10 and input to the second predetermined incident surface 21 is reflected by the predetermined reflecting surfaces 22-1 and 22-2 having power and injected from the second predetermined injection surface 23; and the diaphragm member 30B interposed in the predetermined position between the first optical element 10 and the second optical element 20, wherein the first optical element 10 and the second optical element 20 are connected to each other so that relative positions of the first optical element 10 and the second optical element 20 are maintained in the predetermined relationship,

wherein the first optical element 10 has the engageably shaped portions 215a and 215b formed in the peripheral portion of the effective area 14 on the first injection surface 13 through which the effective luminous flux passes, the engageably shaped portions 215a and 215b respectively corresponding to engageably shaped portions 225a and 225b formed in the peripheral portion of the effective area 24 on the second incident surface 21 of the second optical element 20 through which the effective luminous flux passes,

wherein the second optical element 20 has the engageably shaped portions 225a and 225b formed in the peripheral portion of the effective area 24 on the second incident surface 21 through which the effective luminous flux passes, the engageably shaped portions 225a and 225b respectively corresponding to the engageably shaped portions 215a and 215b provided in the peripheral portion of the effective area 14, through which the effective luminous flux passes, on the first injection surface 13 of the first optical element 10, and

wherein the diaphragm member 30B has, formed in the predetermined portion, the optical diaphragm aperture 33 that permits transmission of the luminous flux from the first injection surface 13 of the first 20 optical element 10 to the second incident surface 21 of the second optical element 20, and

the optical-image forming optical system 350 for imaging the optical image suitable for the image observation from the luminous flux injected from the 25 second predetermined injection surface 23 of the second optical element 20 of the optical element assembly PA.

(17) The image pickup apparatus directed to the thirteenth embodiment is based on the image pickup apparatus described in item (15) and is characterized in that the optical element assembly PA, the image pickup device 210, and the image data producing circuit 230 are configured suitably to be mounted into the housing of the digital camera 200.

(18) The image pickup apparatus directed to the fourteenth embodiment is based on the image pickup apparatus described in item (15) and is characterized in that the optical element assembly PA, the image pickup device 210, and the image data producing circuit 230 are configured suitably to be mounted into the housing of the personal computer 400.

(19) The image pickup apparatus directed to the fifteenth embodiment is based on the image pickup apparatus described in item (15) and is characterized in that the optical element assembly PA, the image pickup device 210, and the image data producing circuit 230 are configured suitably to be mounted into the housing of the mobile phone 500.

Application of the present invention thus directed to each of the above-described twelfth to fifteenth embodiments enables extremely steady provision of the optical element assembly and the image pickup apparatus using the assembly that are required to be miniaturized and thinned.

Furthermore, the optical element assemblies according to the present invention as described above may be applied to various other optical element assemblies for, for example, a PDA (personal digital assistance), which is one of miniature computers, a handheld PC, and a pocket PC.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. An optical element assembly comprising:
a first optical element which includes a prism configured such that incident light arrived from an object and input to a first predetermined incident surface is reflected by a predetermined reflecting surface having power and injected from a first predetermined injection surface;
a second optical element which includes a prism configured such that incident light arrived from the first optical element and input to a second predetermined incident surface is reflected by a predetermined reflecting surface having power and injected from a second predetermined injection surface; and
a positioning holder member to hold the first optical element and the second optical element so that relative positions of the first optical element and the second optical element are maintained in a predetermined relationship,
wherein the first optical element has engageably shaped portions formed in a peripheral portion of an effective area on the first injection surface through which an effective luminous flux passes, the engageably shaped portions respectively corresponding to one engageably shaped portions formed on one opponent surface of the positioning holder member that opposes the first injection surface,
wherein the second optical element has engageably shaped portions formed in a peripheral portion of an effective area on the second incident surface through which an effective luminous flux passes, the engageably shaped portions respectively corresponding to the other engageably shaped portions formed on the other opponent surface of the positioning holder member that opposes the second incident surface, and
wherein the positioning holder member has, formed in a predetermined portion, an optical diaphragm aperture that permits transmission of light between the one opponent surface and the other opponent surface.

2. The optical element assembly according to claim 1, wherein in the first optical element, the engageably shaped portions are individually formed as being protrusion portions.

3. The optical element assembly according to claim 1, wherein the engageably shaped portions are individually formed as being protrusion portions.

4. The optical element assembly according to claim 1, wherein in the positioning holder member, the one engageably shaped portions formed on the one opponent surface are individually formed as being recess portions.

5. The optical element assembly according to claim 1, wherein the other engageably shaped portions formed on the other opponent surface are individually formed as being recess portions.

6. The optical element assembly according to claim 1, wherein in the first optical element, the engageably shaped portions are individually formed as being recess portions.

7. The optical element assembly according to claim 1, wherein in that in the second optical element, the engageably shaped portions are individually formed as being recess portions.

8. The optical element assembly according to claim 1, wherein in the positioning holder member, the one engageably shaped portions formed on the one opponent surface are individually formed as being protrusion portions.

9. The optical element assembly according to claim 1, wherein in the positioning holder member, the other engageably shaped portions formed on the other opponent surface are individually formed as being protrusion portions.

10. The optical element assembly according to claim 1, wherein in the first optical element, first posture adjustment portions to adjust a relative posture of the first optical element to the positioning holder member are formed in the predetermined portions on the first injection surface that are segregated at predetermined distances from the engageably shaped portions and that are out of the effective area.

11. The optical element assembly according to claim 1, wherein in the second optical element, second posture adjustment portions for adjusting a relative posture of the second optical element to the positioning holder member are formed in predetermined portions on the second incident surface that are segregated at predetermined distances from the engageably shaped portions and that are out of the effective area.

12. The optical element assembly according to claim l, wherein in the positioning holder member, first abutment portions that respectively abut the first posture adjustment portions, which are formed on the side of the first optical element to adjust the relative posture thereof to the positioning holder member, are set in predetermined portions of the one opponent surface.

13. The optical element assembly according to claim 1, wherein in the positioning holder member, second abutment portions that respectively abut the second posture adjustment portions, which are formed on the side of the second optical element to adjust the relative posture thereof to the positioning holder member, are set in predetermined portions of the other opponent surface.

14. The optical element assembly according to claim 10, wherein the first posture adjustment portions of the first optical element are individually formed as being semispherical protrusion portions.

15. The optical element assembly according to claim 11, wherein the second posture adjustment portions of the second optical element are individually formed as being semispherical protrusion portions.

16. The optical element assembly according to claim 12, wherein abutting surfaces of the first posture adjustment portions provided on the positioning holder member are individually formed as being semispherical protrusion portions.

17. The optical element assembly according to claim 13, wherein abutting surfaces of the second posture adjustment portions provided on the positioning holder member are individually formed as being semispherical protrusion portions.

18. The optical element assembly according to claim 1, wherein the first optical element has first-optical-element-side abutment portions that respectively abut the first positioning-holder-member-side posture adjustment portions which are formed on the side of the positioning holder member to adjust the posture thereof with respect to the first optical element.

19. The optical element assembly according to claim 1, wherein the first optical element has second-optical-element-side abutment portions that respectively abut the second positioning-holder-member-side posture adjustment portions which are formed on the side of the positioning holder member to adjust the posture thereof with respect to the first optical element.

20. The optical element assembly according to claim 1, wherein
in at least one of the first optical element and the second optical element, the engageably shaped portions are formed as being pyramidal protrusion portions each formed in the shape of a pyramidal body or to include a shaped portion similar to a pyramidal body; and
in the positioning holder member, the engageably shaped portions are formed as being the pyramidal recess portions individually formed to have shapes having surface portions engageable with the pyramidal protrusion portions formed on the side of at least one of the first optical element and the second optical element and along outer circumferential surfaces thereof.

21. The optical element assembly according to claim 1, wherein
in at least one of the first optical element and the second optical element, the engageably shaped portions are individually formed as being pyramidal recess portions in shapes having surface portions along outer circumferential surfaces of pyramidal protrusion portions each formed in a predetermined pyramidal body or to include a shaped portion similar to a portion of a predetermined pyramidal body, and
in the positioning holder member, the engageably shaped portions are formed as being pyramidal protrusion portions individually formed to have shapes engageable with pyramidal recess portions formed on the side of at least one of the first optical element and the second optical element and to have shapes of predetermined pyramidal bodies or shapes each including a shaped portion similar to a portion of a predetermined pyramidal body.

22. An image pickup apparatus comprising:
(A) an optical element assembly comprising:
(a1) a first optical element which includes a prism configured such that incident light arrived from an object and input to a first predetermined incident surface is reflected by a predetermined reflecting surface having power and injected from a first predetermined injection surface;
(a2) a second optical element which includes a prism configured such that incident light arrived from the first optical element and input to a second predetermined incident surface is reflected by a predetermined reflecting surface having power and injected from a second predetermined injection surface; and
(a3) a positioning holder member to hold the first optical element and the second optical element so that relative positions of the first optical element and the second optical element are maintained in a predetermined relationship,
wherein the first optical element has engageably shaped portions formed in a peripheral portion of an effective area on the first injection surface through which an effective luminous flux passes, the engageably shaped portions respectively corresponding to one engageably shaped portions formed on one opponent surface of the positioning holder member that opposes the first injection surface,
wherein the second optical element has engageably shaped portions formed in a peripheral portion of an effective area on the second incident surface through which an effective luminous flux passes, the engageably shaped portions respectively corresponding to the other engageably shaped portions formed on the other opponent surface of the positioning holder member that opposes the second incident surface, and
wherein the positioning holder member has, formed in a predetermined portion, an optical diaphragm aperture that permits transmission of light between the one opponent surface and the other opponent surface, and
(B) an image pickup device adapted to perform photoelectrical conversion of an optical image of a luminous flux injected from the predetermined injection surface of the optical element assembly; and
(C) an image data producing circuit to produce image data adaptable to at least one of predetermined recording and communication in accordance with an output signal of the image pickup device.

23. An image pickup apparatus comprising:
(A) an optical element assembly comprising:
(a1) a first optical element which includes a prism configured such that incident light arrived from the side of an object and input to a first predetermined incident surface is reflected by a first predetermined reflecting surface having power and injected from a first predetermined injection surface;
(a2) a second optical element which includes a prism configured such that incident light arrived from the first optical element and input to a second predetermined incident surface is reflected by predetermined reflecting surfaces having power and injected from a second predetermined injection surface; and
(a3) a positioning holder member to hold the first optical element and the second optical element so that relative positions of the first optical element and the second optical element are maintained in a predetermined relationship,
wherein the first optical element comprises engageably shaped portions in a peripheral portion of an effective area on the first injection surface through which the effective luminous flux passes, the engageably shaped portions respectively corresponding to first engageably shaped portions formed on one opponent surface of the positioning holder member that opposes the first injection surface,
wherein the second optical element comprises engageably shaped portions in the peripheral portion of the effective area on the second incident surface through which the effective luminous flux passes, the engageably shaped portions respectively corresponding to second engageably shaped portions formed on the other opponent surface of the positioning holder member that opposes the second incident surface, and
wherein the positioning holder member comprises in a predetermined portion an optical diaphragm aperture that permits transmission of light between the one opponent surface and the other opponent surface, and
(B) an optical-image forming optical system to image an optical image suitable for image observation from a luminous flux injected from the second predetermined injection surface of the second optical element of the optical element assembly.

24. The image pickup apparatus according to claim 22, wherein the optical element assembly, the image pickup device, and the image data producing circuit are configured suitably to be mounted into a housing of a digital camera.

25. The optical element assembly according to claim 22, wherein the optical element assembly, the image pickup device, and the image data producing circuit are configured suitably to be mounted into a housing of a personal computer.

26. The optical element assembly according to claim 22, wherein the optical element assembly, the image pickup device, and the image data producing circuit are configured suitably to be mounted into a housing of a mobile phone.

27. An optical element assembly comprising:
a first optical element which includes a prism configured such that incident light arrived from an object and input to a first predetermined incident surface is reflected by a predetermined reflecting surface having power and injected from a first predetermined injection surface;
a second optical element which includes a prism configured such that incident light arrived from the first optical element and input to a second predetermined incident surface is reflected by a predetermined reflecting surface having power and injected from a second predetermined injection surface; and
a positioning holder member to hold the first optical element and the second optical element so that relative positions of the first optical element and the second optical element are maintained in a predetermined relationship,
wherein the first optical element has engageable protrusion portions formed in a peripheral portion of an effective area on the first injection surface through which an effective luminous flux passes, the engageable protrusion portions being provided to engage one opponent surface of a positioning holder member that opposes the first injection surface,
wherein the second optical element has engageable protrusion portions formed in a peripheral portion of an effective area on the second incident surface through which an effective luminous flux passes, the engageable protrusion portions being provided to engage the other opponent surface of the positioning holder member that opposes the second incident surface,
wherein the positioning holder member has, formed in a predetermined portion, an optical diaphragm aperture that permits transmission of light between the one opponent surface and the other opponent surface, and additionally comprises, respectively on the one opponent surface and the other opponent surface, engageable recess portions that are formed to respectively correspond to and to be engageable with the engageable protrusion portions of the first optical element and the engageable protrusion portions of the second optical element.

28. The optical element assembly according to claim 27, wherein the positioning holder member is formed of an optical-shield material.

29. The optical element assembly according to claim 27, wherein the positioning holder member comprises an optical-shield film formed on a predetermined portion of an outer surface of its own.

30. An image pickup apparatus comprising:
(A) an optical element assembly comprising:
(a1) a first optical element which includes a prism configured such that incident light arrived from an object and input to a first predetermined incident surface is reflected by a predetermined reflecting surface having power and injected from a first predetermined injection surface;
(a2) a second optical element which includes a prism configured such that incident light arrived from the first optical element and input to a second predetermined incident surface is reflected by a predetermined reflecting surface having power and injected from a second predetermined injection surface; and
(a3) a positioning holder member to hold the first optical element and the second optical element so that relative positions of the first optical element and the second optical element are maintained in a predetermined relationship,
wherein the first optical element has engageable protrusion portions formed in a peripheral portion of an effective area on the first injection surface through which an effective luminous flux passes, the engageable protrusion portions being provided to engage one opponent surface of the positioning holder member that opposes the first injection surface,
wherein the second optical element has engageable protrusion portions formed in a peripheral portion of an effective area on the second incident surface through which an effective luminous flux passes, the engageable protrusion portions being provided to engage the other opponent surface of the positioning holder member that opposes the second incident surface,
wherein the positioning holder member has, formed in a predetermined portion, an optical diaphragm aperture that permits transmission of light between the one opponent surface and the other opponent surface, and additionally has, respectively on the one opponent surface and the other opponent surface, engageable recess portions that are formed to respectively correspond to and to be engageable with the engageable protrusion portions of the first optical element and the engageable protrusion portions of the second optical element, and
(B) an image pickup device adapted to perform photoelectrical conversion of an optical image of a luminous flux injected from the predetermined injection surface of the optical element assembly; and
(C) an image data producing circuit to produce image data adaptable to at least one of predetermined recording and communication in accordance with an output signal of the image pickup device.

31. An image pickup apparatus comprising:
(A) an optical element assembly comprising:
(a1) a first optical element which includes a prism configured such that incident light arrived from an object and input to a first predetermined incident surface is reflected by a predetermined reflecting surface having power and injected from a second predetermined injection surface;
(a2) a second optical element which includes a prism configured such that incident light arrived from the first optical element and input to a second predetermined incident surface is reflected by predetermined reflecting surfaces having power and injected from a second predetermined injection surface; and
(a3) a positioning holder member to hold the first optical element and the second optical element so that relative positions of the first optical element and the second optical element are maintained in a predetermined relationship,
wherein the first optical element comprises engageable protrusion portions in a peripheral portion of an effective area on the first injection surface through which the effective luminous flux passes, the engageable protrusion portions being provided to engage one opponent surface of the positioning holder member that opposes the first injection surface,
wherein the second optical element comprises engageable protrusion portions in a peripheral portion of an effective area on the second incident surface through which the effective luminous flux passes, the engageable protrusion portions being provided to engage the other opponent surface of the positioning holder member that opposes the second incident surface, and
wherein the positioning holder member comprises in a predetermined portion an optical diaphragm aperture that permits transmission of light between the one opponent surface and the other opponent surface, and additionally comprises, respectively on the one opponent surface and the other opponent surface, engageable recess portions that are formed to respectively correspond to and to be engageable with the engageable protrusion portions of the first optical element and engageable protrusion portions of the second optical element, and
(B) an optical-image forming optical system to image the optical image suitable for the image observation from a luminous flux injected from the second predetermined injection surface of the second optical element of the optical element assembly.

32. The image pickup apparatus according to claim 30, wherein the optical element assembly, the image pickup device, and the image data producing circuit are configured suitably to be mounted into a housing of a digital camera.

33. The image pickup apparatus according to claim 30, wherein the optical element assembly, the image pickup device, and the image data producing circuit are configured suitably to be mounted into a housing of a personal computer.

34. The optical element assembly according to claim 30, wherein the optical element assembly, the image pickup device, and the image data producing circuit are configured suitably to be mounted into a housing of a mobile phone.

35. An optical element assembly comprising:
a first optical element which includes a prism configured such that incident light arrived from an object and input to a first predetermined incident surface is reflected by a predetermined reflecting surface having power and injected from a first predetermined injection surface;
a second optical element which includes a prism configured such that incident light arrived from the first optical element and input to a second predetermined incident surface is reflected by a predetermined reflecting surface having power and injected from a second predetermined injection surface; and
a diaphragm member which connects the first optical element and the second optical element so that relative positions of the first optical element and the second optical element are maintained in a predetermined relationship, and which is interposed in a predetermined position between the first optical element and the second optical element,
wherein the first optical element has engageably shaped portions formed in a peripheral portion of an effective area on the first injection surface through which an effective luminous flux passes, the engageably shaped portions respectively corresponding to engageably shaped portions formed in a peripheral portion of an effective area on the second incident surface of the second optical element through which an effective luminous flux passes,
wherein the second optical element has the engageably shaped portions formed in the peripheral portion of an effective area on the second incident surface through which the effective luminous flux passes, the engageably shaped portions respectively corresponding to the engageably shaped portions provided in the peripheral portion of the effective area, through which the effective luminous flux passes, on the first injection surface of the first optical element, and
wherein the diaphragm member has, formed in a predetermined portion, an optical diaphragm aperture that permits transmission of the luminous flux from the first injection surface of the first optical element to the second incident surface of the second optical element.

36. The optical element assembly according to claim 35, wherein in the first optical element, the engageably shaped portions are individually formed as being recess portions.

37. The optical element assembly according to claim 35, wherein in the second optical element, the engageably shaped portions are individually formed as being protrusion portions.

38. The optical element assembly according to claim 35, wherein in the first optical element, the engageably shaped portions are individually formed as being protrusion portions.

39. The optical element assembly according to claim 35, wherein in the second optical element, the engageably shaped portions are individually formed as being recess portions.

40. The optical element assembly according to claim 36, wherein in the second optical element, in the recess portions, shield materials are individually provided in predetermined regions including recessed bottom portions and vicinities thereof.

41. The optical element assembly according to claim 37, wherein in the protrusion portions of the second optical element, shield materials are individually provided in predetermined regions including protrusion ends portions and the vicinities thereof.

42. The optical element assembly according to claim 38, wherein in the protrusion portions of the first optical element, shield materials are individually provided in predetermined regions including protrusion ends portions and the vicinities thereof.

43. The optical element assembly according to claim 39, wherein in the recess portions of the second optical element, shield materials are individually provided in predetermined regions including recessed bottom portions and the vicinities thereof.

44. The optical element assembly according to claim 35, wherein in the second optical element, posture adjustment portions for adjusting the relative posture to the first optical element are formed in a predetermined portions on the second incident surface that are segregated at predetermined distances from the engageably shaped portions of the second optical element and that are out of the effective area.

45. The optical element assembly according to claim 35, wherein in the first optical element, posture adjustment portions for adjusting the relative posture to the second optical element are formed in predetermined portions on the first injection surface that are segregated at the predetermined distances from the engageably shaped portions and that are out of the effective area.

46. The optical element assembly according to claim 44, wherein the posture adjustment portions are individually formed as being protrusion portions.

47. The optical element assembly according to claim 45, wherein the posture adjustment portions are individually formed as being protrusion portions.

48. The optical element assembly according to claim 35, wherein in the first optical element, abutment portions to abut respective posture adjustment portions formed on the second optical element to adjust the posture with respect to the relative position are individually set in predetermined portions on the first injection surface.

49. The optical element assembly according to claim 35, wherein in the second optical element, abutment portions to abut respective posture adjustment portions formed on the first optical element to adjust the posture with respect to the relative position are individually set in predetermined portions on the second incident surface.

50. An image pickup apparatus comprising:
(A) an optical element assembly comprising:
(a1) a first optical element which includes a prism configured such that incident light arrived from an object and input to a first predetermined incident surface is reflected by a predetermined reflecting surface having power and injected from a second predetermined injection surface;
(a2) a second optical element which includes a prism configured such that incident light arrived from the first optical element and input to a second predetermined incident surface is reflected by a predetermined reflecting surface having power and injected from a second predetermined injection surface, the first optical element and the second optical element being connected to each other so that relative positions of the first optical element and the second optical element are maintained in the predetermined relationship; and
(a3) a diaphragm member interposed in a predetermined position between the first optical element and the second optical element,
wherein the first optical element has engageably shaped portions formed in a peripheral portion of an effective area on the first injection surface through which an effective luminous flux passes, the engageably shaped portions respectively corresponding to engageably shaped portions formed in a peripheral portion of an effective area on the second incident surface of the second optical element through which an effective luminous flux passes,
wherein the second optical element has the engageably shaped portions formed in the peripheral portion of an effective area on the second incident surface through which the effective luminous flux passes, the engageably shaped portions respectively corresponding to the engageably shaped portions provided in the peripheral portion of the effective area, through which the effective luminous flux passes, on the first injection surface of the first optical element, and
wherein the diaphragm member has, formed in a predetermined portion, an optical diaphragm aperture that permits transmission of the luminous flux from the first injection surface of the first optical element to the second incident surface of the second optical element, and
(B) an image pickup device adapted to perform photoelectrical conversion of an optical image of a luminous flux injected from the predetermined injection surface of the optical element assembly; and
(C) an image data producing circuit to produce image data adaptable to at least one of predetermined recording and communication in accordance with an output signal of the image pickup device.

51. An image pickup apparatus comprising:
(A) an optical element assembly comprising:
(a1) a first optical element which includes a prism configured such that incident light arrived from an object and input to a first predetermined incident surface is reflected by a predetermined reflecting surface having power and injected from a first predetermined injection surface;
(a2) a second optical element which includes a prism configured such that incident light arrived from the first optical element and input to a second predetermined incident surface is reflected by predetermined reflecting surfaces having power and injected from a second predetermined injection surface, the first optical element and the second optical element being connected to each other so that relative positions of the first optical element and the second optical element are maintained in the predetermined relationship; and
(a3) a diaphragm member interposed in a predetermined position between the first optical element and the second optical element,
wherein the first optical element comprises engageably shaped portions in a peripheral portion of an effective area on the first injection surface through which the effective luminous flux passes, engageably shaped portions respectively corresponding to engageably shaped portions formed in a peripheral portion of an effective area on the second incident surface of the second optical element through which the effective luminous flux passes,
wherein the second optical element has engageably shaped portions in a peripheral portion of an effective area on the second incident surface through which the effective luminous flux passes, the engageably shaped portions respectively corresponding to the engageably shaped portions provided in the peripheral portion of the effective area, through which the effective luminous flux passes, on the first injection surface of the first optical element, and
wherein the diaphragm member comprises an optical diaphragm aperture that permits transmission of the luminous flux from the first injection surface of the first optical element to the second incident surface of the second optical element, and
(B) an optical-image forming optical system to image the optical image suitable for the image observation from a luminous flux injected from the second predetermined injection surface of the second optical element of the optical element assembly.

52. The image pickup apparatus according to claim 50, wherein the optical element assembly, the image pickup device, and the image data producing circuit are configured suitably to be mounted into a housing of a digital camera.

53. The image pickup apparatus according to claim 50, wherein the optical element assembly, the image pickup device, and the image data producing circuit are configured suitably to be mounted into a housing of a personal computer.

54. The optical element assembly according to claim 50, wherein the optical element assembly, the image pickup device, and the image data producing circuit are configured suitably to be mounted into a housing of a mobile phone.
